(19) United States
(12) Patent Application Publication
(10) Pub. No.: US 2024/0162278 A1
(43) Pub. Date: May 16, 2024

(54) CAPACITOR STRUCTURE AND SEMICONDUCTOR DEVICE INCLUDING SAME

(71) Applicant: SAMSUNG ELECTRONICS CO., LTD., SUWON-SI (JP)

(72) Inventors: KYOOHO JUNG, SUWON-SI (KR); JINWOOK LEE, SUWON-SI (KR); JONGYEONG MIN, SUWON-SI (KR); JIYE BAEK, SUWON-SI (KR); YESEUL LEE, SUWON-SI (KR)

(21) Appl. No.: 18/367,915

(22) Filed: Sep. 13, 2023

(30) Foreign Application Priority Data
Nov. 15, 2022 (KR) 10-2022-0152400

(51) Int. Cl. H01G 4/012; H01G 4/08; H10B 12/00

(52) U.S. Cl. CPC H01L 28/75; H01G 4/012; H01G 4/085; H01L 28/87; H01L 28/91; H10B 12/315; H10B 12/0335

(57) ABSTRACT

A capacitor structure includes; a lower electrode, a dielectric pattern on the lower electrode, an interface structure on the dielectric pattern, and an upper electrode on the interface structure. The dielectric pattern includes an oxide of a metal having 4 valence electrons. The interface structure includes a first interface pattern including a first metal oxide doped with nitrogen, and a second interface including a second metal oxide.

### CROSS-REFERENCE TO RELATED APPLICATION

This application claims priority under 35 U.S.C. § 119 to Korean Patent Application No. 10-2022-0152400 filed on Nov. 15, 2022 in the Korean Intellectual Property Office, the subject matter of which is hereby incorporated by reference in its entirety.

### BACKGROUND

Embodiments of the inventive concept relate to capacitor structures and semiconductor devices including same.

A capacitor in a semiconductor device may include a sequentially stacked arrangement of a lower electrode, a dielectric layer and an upper electrode. As the thickness of the dielectric layer decreases, capacitance of the capacitor increases, but leakage current associated with the capacitor also increases.

### SUMMARY

Embodiments of the inventive concept provide capacitor structures exhibiting improved performance characteristics, as well as various semiconductor devices including such capacitor structures.

According to some embodiments of the inventive concept, a capacitor structure may include; a lower electrode, a dielectric pattern on the lower electrode, wherein the dielectric pattern includes an oxide of a metal having 4 valence electrons, an interface structure on the dielectric pattern, wherein the interface structure includes a first interface pattern including a first metal oxide doped with nitrogen, and a second interface pattern including a second metal oxide, and an upper electrode on the interface structure.

According to some embodiments of the inventive concept, a capacitor structure may include; a lower electrode, a dielectric pattern on the lower electrode and having a first thickness, wherein the dielectric pattern includes an oxide of a first metal, a first interface pattern on the dielectric pattern and having a second thickness less than the first thickness, the first interface pattern including an oxynitride of a second metal and a third metal, wherein the second metal is different from the third metal, a second interface pattern the first interface pattern and having a third thickness less than the first thickness, the second interface pattern including an oxide of the second metal and the third metal, and an upper electrode on the second interface pattern.

According to some embodiments of the inventive concept, a semiconductor device may include; a bit line structure on a substrate, a gate electrode on the bit line, wherein the gate electrode is spaced apart from the bit line, a gate insulation pattern on a sidewall of the gate electrode, a channel on a sidewall of the gate insulation pattern, wherein the channel includes an oxide semiconductor material, a contact plug structure contacting an upper surface of the channel, and a capacitor structure on the contact plug structure, wherein the capacitor structure includes; a lower electrode, a dielectric pattern on the lower electrode and including an oxide of a metal having 4 valence electrons, an interface structure including a first interface pattern on the dielectric pattern, the first interface pattern including a first metal oxide doped with nitrogen, and a second interface pattern on the first interface pattern, the first interface pattern including a second metal oxide, and an upper electrode on the interface structure.

### BRIEF DESCRIPTION OF THE DRAWINGS

Advantages, benefits and features, as well as the making and use of the inventive concept may be clearly understood upon consideration of the following detailed description together with the accompanying drawings, in which;

FIG. 1 is a cross sectional view illustrating a capacitor structure according to embodiments of the inventive concept;

FIG. 2 is an enlarged cross-sectional view further illustrating region ‘X’ indicated in FIG. 1;

FIGS. 3, 4, 5, 6, 7, 8, 9, 10, 11 and 12 (hereafter collectively, “FIGS. 3 to 12”) are related cross-sectional views illustrating in one example a method of forming a capacitor structure device according to embodiments of the inventive concept, wherein FIGS. 8, 10 and 12 are enlarged cross-sectional views further illustrating region ‘X’ respectively indicated in FIGS. 7, 9 and 11;

FIG. 13 is a graph comparing leakage current associated with an example embodiment of the inventive concept with a comparative, conventional example;

FIG. 14 is a plan (or top-down) view illustrating a semiconductor device according to embodiments of the inventive concept;

FIG. 15 is a cross-sectional view taken along line A-A′ of FIG. 14;

FIGS. 16, 17, 18, 19, 20, 21, 22, 23, 24, 25, 26, 27, 28, 29, 30 and 31 (hereafter collectively, “FIGS. 16 to 31”) are related views illustrating in one example a method of manufacturing a semiconductor device according to embodiments of the inventive concept, wherein FIGS. 16, 18, 21, 25, and 29 are plan views and FIGS. 17, 19, 20, 22, 23, 24, 26, 27, 28, 30 and 31 are cross sectional views;

FIG. 32 is a plan view illustrating a semiconductor device according to embodiments of the inventive concept;

FIG. 33 is a cross-sectional view taken along line A-A′ of FIG. 32;

FIGS. 34, 35, 36, 37, 38, 39, 40, 41, 42, 43 and 44 (hereafter collectively, “FIGS. 34 to 44”) are related cross sectional views illustrating in one example a method of manufacturing a semiconductor device according to embodiments of the inventive concept; and

FIG. 45 is a cross sectional view illustrating a semiconductor device according to embodiments of the inventive concept.

### DETAILED DESCRIPTION

Throughout the written description and drawings, like reference numbers and labels are used to denote like or similar elements, components, features and/or method steps. Throughout the written description certain geometric terms may be used to highlight relative relationships between elements, components and/or features with respect to certain some embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

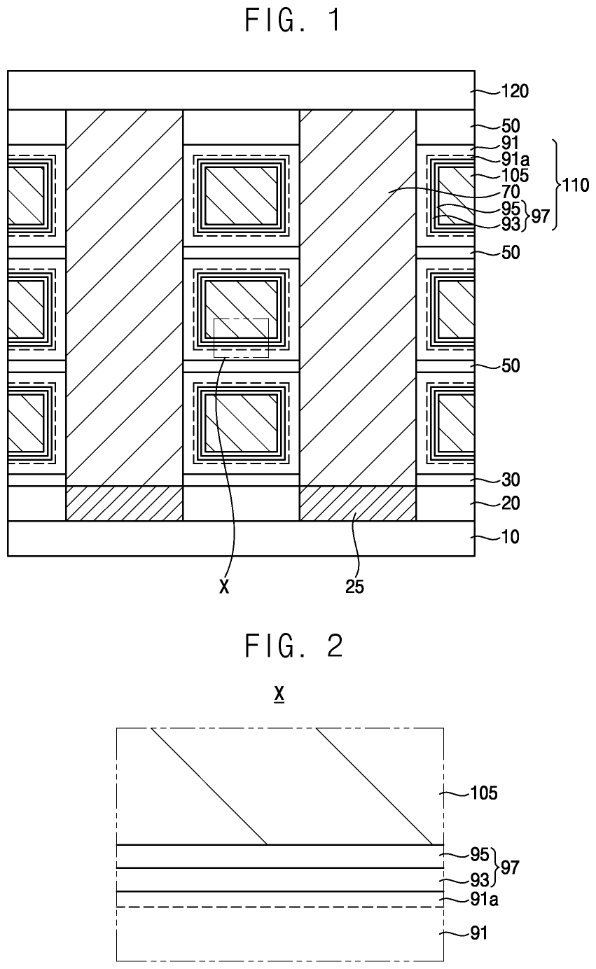

FIGS. 1 and 2 are cross sectional views illustrating a capacitor structure according to embodiments of the inventive concept, wherein FIG. 2 is an enlarged cross-sectional view further illustrating region ‘X’ indicated in FIG. 1.

Referring to FIGS. 1 and 2, the capacitor structure may include a capacitor 110, a support layer 50 and an upper electrode plate 120 on a substrate 10. The capacitor 110 may include a lower electrode 70, a dielectric pattern 91, an interface structure 97 and an upper electrode 105. The capacitor structure may further include an insulating interlayer 20 including a conductive pattern 25 on the substrate 10, and a first etch stop layer 30.

The substrate 10 may include at least one of, for example, silicon, germanium, silicon-germanium, and a □-□ group compound semiconductor, such as GaP, GaAs, and GaSb. In some embodiments, the substrate 10 may be a silicon-on-insulator (SOI) substrate or a germanium-on-insulator (GOI) substrate.

The first conductive pattern 25 may include, for example, a contact plug and a landing pad. Here, the first conductive patterns 25 may be spaced apart in a horizontal direction substantially parallel to an upper surface of the substrate 10.

The first insulating interlayer 20 may include an oxide, such as silicon oxide or a low-k material. The first conductive pattern 25 may include, for example, a metal, a metal nitride, a metal silicide, doped polysilicon, etc.

The first etch stop layer 30 may be formed on the first insulating interlayer 20. The first etch stop layer 30 may include a nitride, such as silicon boron nitride (SiBN) or silicon carbonitride (SiCN).

The lower electrode 70 may extend through the first etch stop layer 30 to contact an upper surface of the first conductive pattern 25, and may have a pillar shape extending in a vertical direction substantially perpendicular to the upper surface of the substrate 10. However, the inventive concept may not be limited thereto, and lower electrode 70 may alternately have a shape such as a cup or a hollow cylinder. Here, if the lower electrode 70 has a cup shape, a filling pattern including at least one of, for example, a semiconductor material like amorphous silicon or an insulating material, may be formed in a space defined by the lower electrode 70.

The lower electrode 70 may include a metal nitride, such as titanium nitride.

The support layer 50 may be formed on a sidewall of each of the lower electrodes 70. The support layer 50 may have a plate shape including lower and upper surfaces substantially parallel to the upper surface of the upper surface of the substrate 10. The support layer 50 may include an insulating nitride, such as silicon nitride (SiN), silicon boron nitride (SiBN), and silicon carbonitride (SiCN).

The dielectric pattern 91 may contact a sidewall of each of the lower electrodes 70 between the first etch stop layer 30 and a lowermost one of the support layers 50, as well as between adjacent, vertically-stacked support layers 50. In some embodiments, the dielectric pattern 91 may include a metal oxide, wherein the metal has four (4) valence electrons, such as hafnium or zirconium.

In some embodiments, a portion of the dielectric pattern 91 adjacent to the interface structure 97 may further include nitrogen (N), which may be referred to as a nitrogen including portion 91a. Thus, the nitrogen including portion 91a may include, for example, hafnium oxynitride and/or zirconium oxynitride.

In some embodiments, the dielectric pattern 91 may have a thickness that ranges from between about 30 Å to about 60 Å.

The interface structure 97 may include first and second interface patterns 93 and 95 sequentially stacked on a surface of the dielectric pattern 91. The interface structure 97 may be disposed between the first etch stop layer 30 and the lowermost one of the support layers 50, as well as between adjacent vertically-stacked support layers 50. Accordingly, the first interface pattern 93 may contact the surface of the dielectric pattern 91, and the second interface pattern 95 may contact a surface of the upper electrode 105.

The first interface pattern 93 may include a first metal oxide doped with nitrogen (N), and the second interface pattern 95 may include a second metal oxide. In some embodiments, the first metal may include at least one, for example, titanium and niobium. In some embodiments, the second metal may include at least one of, for example, niobium, tantalum, vanadium and tin.

Accordingly, the first interface pattern 93 may include, for example, Ti_{1-(x+y)}O_{X}N_{Y}, Nb_{1-(x+y)}OₓN_{y}, Ti_{1-(x+y+z)}NbₓO_{y}N_{z} etc., and the second interface pattern 95 may include, for example, Ti₁₋ₓO_{X}, Nb₁₋ₓO_{X}, Ti_{1-(x+y)}NbₓO_{y}.

In some embodiments, the first interface pattern 93 may have a thickness that ranges from between about 30 Å to about 10 Å, and the second interface pattern 95 may have a thickness that ranges from between about 5 Å to about 10 Å. Accordingly, each of the first and second interface patterns 93 and 95 may be thinner than the dielectric pattern 91.

The first interface pattern 93 may include the first metal oxide doped with nitrogen. Thus, the first interface pattern 93 may have a conductivity greater than a conductivity of the first metal oxide.

In some embodiments, the first interface pattern 93 may have a dielectric constant that ranges from between about 5 to about 30.

The interface structure 97 may cover the surface of the upper electrode 105, and the upper electrode 105 may be formed between the first etch stop layer 30 and the lowermost one of the support layers 50, and between the support layers 50.

The upper electrode 105 may include a metal nitride, such as titanium nitride. The upper electrode 105 may include a material substantially the same as (or alternately different from) a material of the lower electrode 70.

The upper electrode plate 120 may be formed on the lower electrode 70 and an uppermost one of the support layers 50, and may include, for example, doped silicon-germanium.

Generally, the capacitance of a capacitor increases as a thickness of a dielectric pattern between upper and lower electrodes decreases. However, as the thickness of the dielectric pattern decreases, leakage current may also increase. In some embodiments, the interface structure 97 may be disposed between the dielectric pattern 91 and the upper electrode 105, so as to effectively decrease leakage current associated with the capacitor 110.

If the interface structure 97 includes a metal oxide, the metal oxide may also serve as a dielectric material together with the dielectric pattern 91, which may result in an increase in the total thickness of a dielectric structure. Accordingly, capacitance of the capacitor 110 may decrease.

However, in embodiments of the inventive concept, the interface structure 97 of the capacitor 110 does not simply include a metal oxide, but instead, may include the first interface pattern 93 including the first metal oxide doped with nitrogen and the second interface pattern 95 including the second metal oxide.

The first interface pattern 93 including the first metal oxide doped with nitrogen may have an increased conductivity greater than that of the first metal oxide, and may be formed between the dielectric pattern 91 and the second interface pattern 95. Accordingly, the second interface pattern 95 need not serve as a dielectric material, and this relationship precludes increase in the total thickness of the dielectric structure. Thus, the capacitance of the capacitor 110 including the interface structure 97 need not decrease.

Accordingly, the capacitor 110 may exhibit a reduced leakage current due to the presence of the interface structure 97, while the capacitance of the capacitor 110 is not decreased due to the presence of the interface structure 97. That is, the capacitor 110, consistent with embodiments of the inventive concept, exhibits improved electrical performance characteristics.

In some embodiments, the interface structure 97 including the first and second interface pattern 93 and 95 may be disposed not only between the dielectric pattern 91 and the upper electrode 105, but also between the dielectric pattern 91 and the lower electrode 70. Accordingly, the first interface pattern 93 may contact the surface of the dielectric pattern 91, and the second interface pattern 95 may contact a surface of the lower electrode 70.

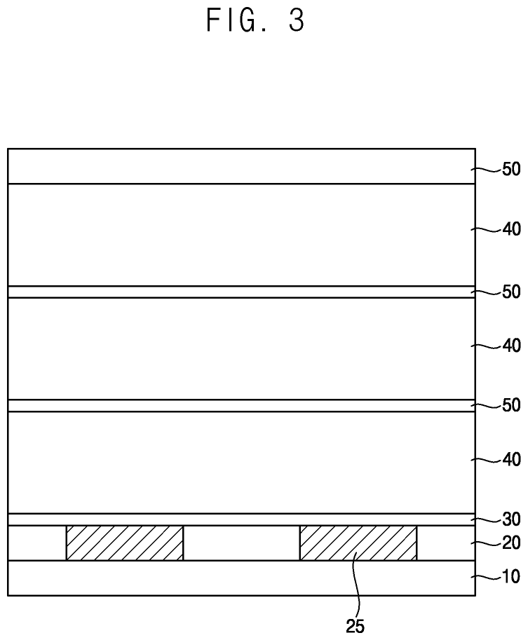

FIGS. 3 to 12 are related views illustrating in one example a method of forming a capacitor structure according to embodiments of the inventive concept.

Referring to FIG. 3, the first insulating interlayer 20 including the first conductive patterns 25 may be formed on the substrate 10, the first etch stop layer 30 may be formed on the first conductive pattern 25 and the first insulating interlayer 20, and a mold layer 40 and the support layer 50 may be alternately stacked on the first etch stop layer 30.

In some embodiments, the first conductive patterns 25 may be spaced apart in a horizontal direction substantially parallel to an upper surface of the substrate 10.

The mold layer 40 may include at least one of, for example, silicon oxide and a low-k material.

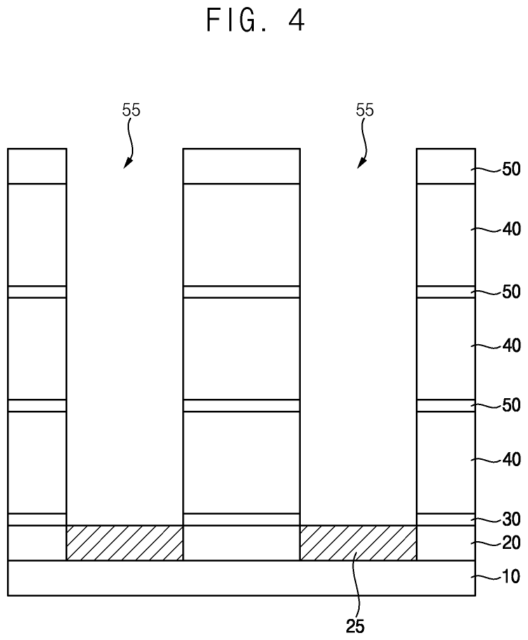

Referring to FIG. 4, a first opening 55 may formed through the support layer 50, the mold layer 40 and the first etch stop layer 30 to expose respective upper surfaces of the first conductive patterns 25.

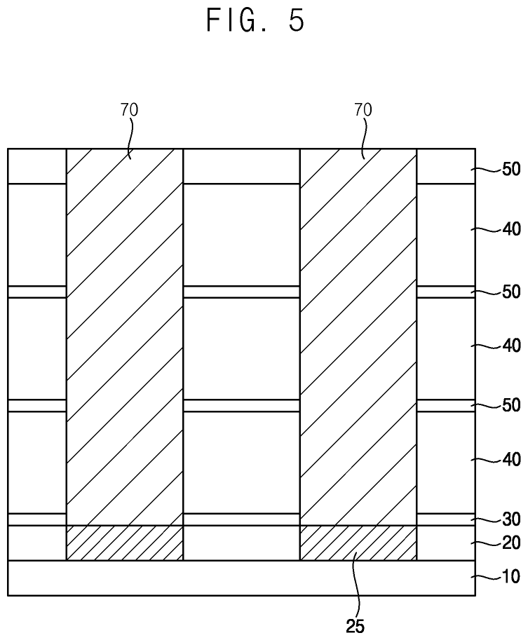

Referring to FIG. 5, a lower electrode layer may be formed on the upper surface of the first conductive patterns 25 and an upper surface of an uppermost one of the support layers 50 to fill the first opening 55. The lower electrode layer may be planarized until the upper surface of the uppermost one of the support layers 50 is exposed, and thus the lower electrode 70 may be formed in the first opening 55.

The planarization process used during this method step may include at least one of, for example, a chemical mechanical polishing (CMP) process and an etch back process.

In some embodiments, the lower electrode layer may be formed by the use of, for example, a deposition process using a metal source gas, such as a titanium source gas and a nitrogen source gas (e.g., ammonia). Accordingly, the lower electrode layer may include a metal nitride (e.g., titanium nitride).

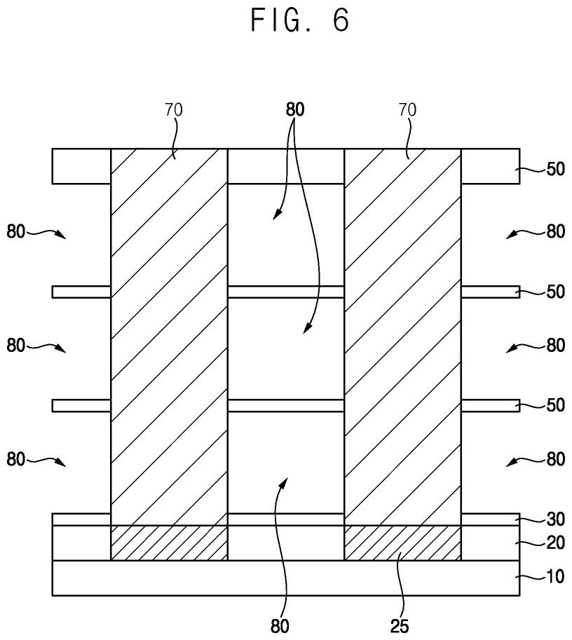

Referring to FIG. 6, the support layer 50 and the mold layer 40 may be partially removed to form a second opening exposing an upper surface of the first etch stop layer 30, wherein the mold layer 40 may be removed through the second opening.

In some embodiments, portions of the mold layer 40 may be removed by the use of, for example, a wet etch process, to form third openings 80 selectively exposing a sidewall of the lower electrode 70. (Here, however, the support layers 50 will remain on the sidewall of each of the lower electrodes 70). Accordingly, the upper surface of the first etch stop layer 30 and surfaces of the support layers 50 may also be exposed by the formation of the third openings 80.

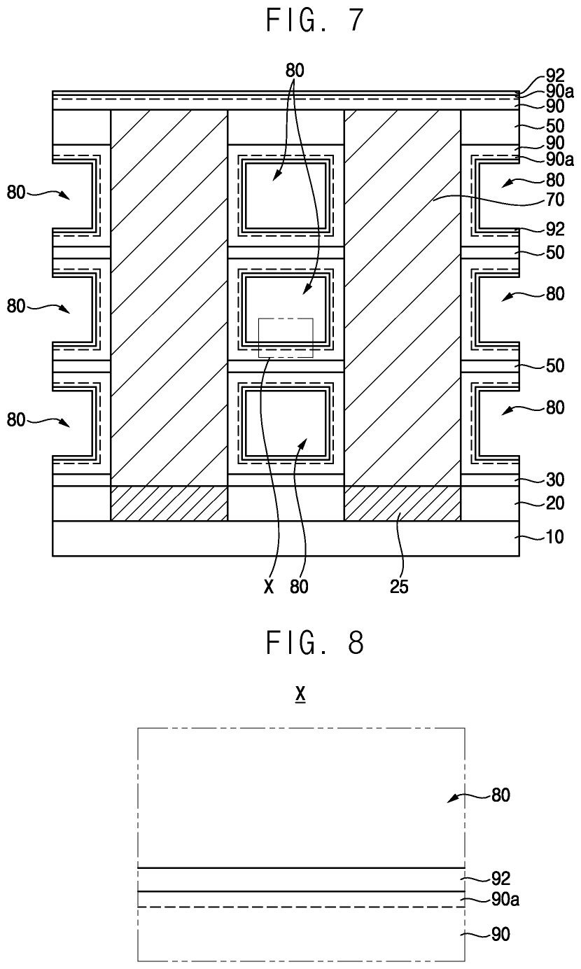

Referring to FIGS. 7 and 8, the dielectric layer 90 may be formed on the sidewall of each of the lower electrodes 70, the upper surface of the first etch stop layer 30 and the surfaces of the support layers 50 exposed by the third openings 80.

In some embodiments, the dielectric layer 90 may be formed by the use of, for example, a deposition process using a metal source gas, such as hafnium and zirconium, having 4 valence electrons, and an oxygen source (e.g., ozone plasma). Accordingly, the dielectric layer 90 may include an oxide, such as for example, hafnium oxide or zirconium oxide.

A first preliminary interface layer may be formed on a surface of the dielectric layer 90. Here, the first preliminary interface layer may be formed by the use of, for example, a deposition process using a first metal source gas (e.g., titanium or niobium) and an oxide source gas (e.g., ozone plasma).

A heat treatment process and/or a plasma treatment process may be performed on the first preliminary interface layer in an atmosphere including a nitrogen source gas (e.g., nitrogen (N₂) or ammonia (NH₃)). Accordingly, the first preliminary interface layer may be converted to a first interface layer 92 including the first metal oxide doped with nitrogen (N).

In some embodiments, during the heat treatment process and/or the plasma treatment process, nitrogen(N) may penetrate into at least a portion of the dielectric layer 90 adjacent to the first preliminary interface layer. Accordingly, the portion of the dielectric layer 90 may be converted into a preliminary nitrogen including portion 90a.

The dielectric layer 90 and the first interface layer 92 may also be stacked on an upper surface of the lower electrode 70 and the upper surface of the uppermost one of the support layers 50.

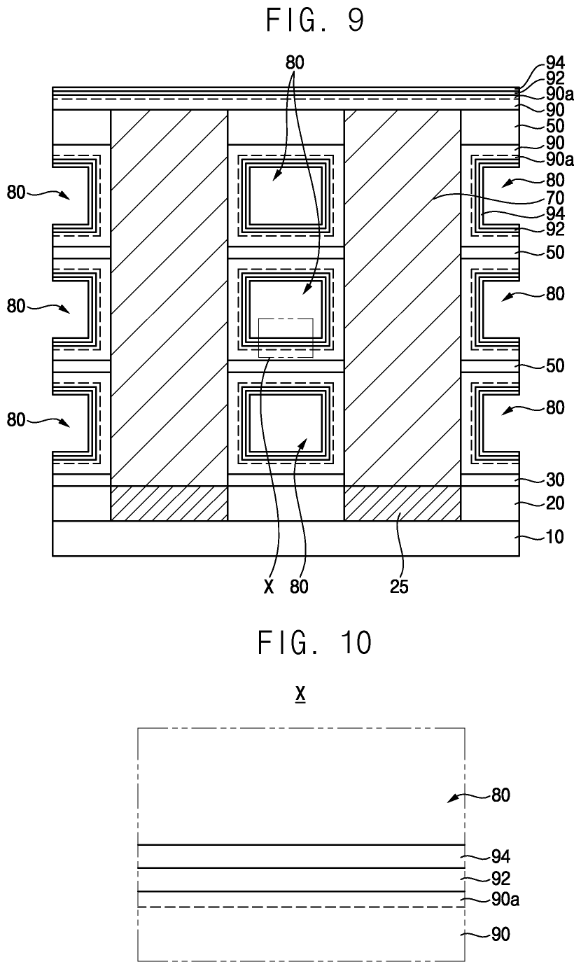

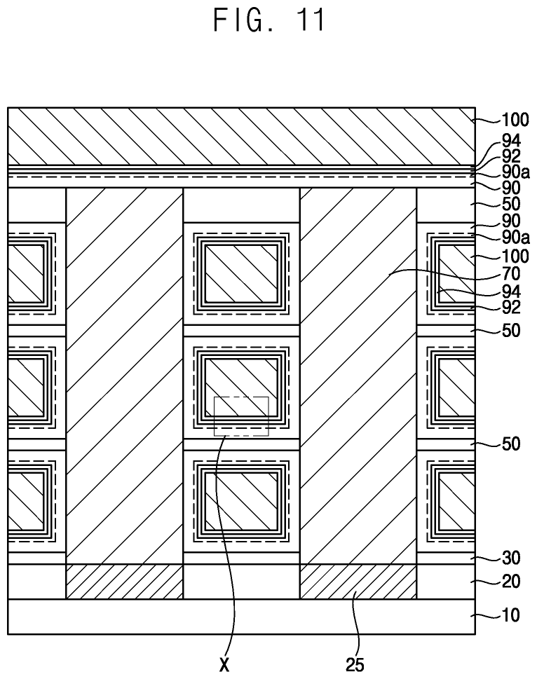

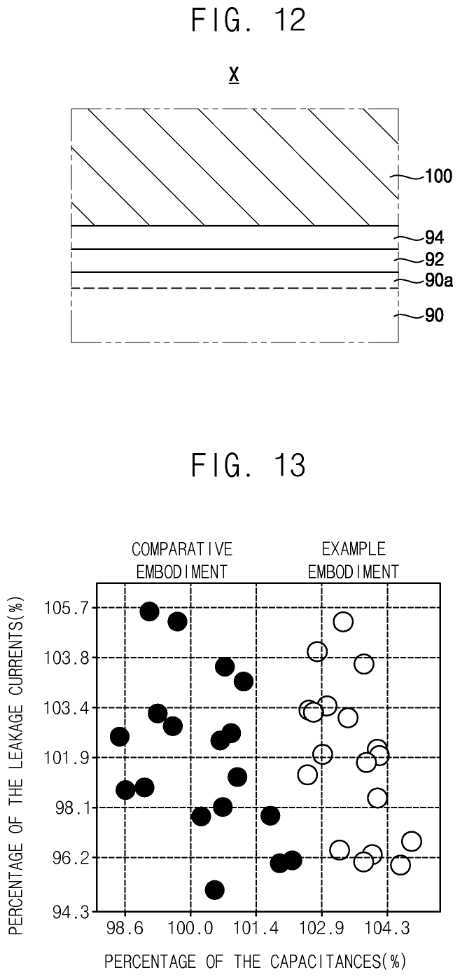

Referring to FIGS. 9 and 10, a second interface layer 94 may be formed on the first interface layer 92. Here, the second interface layer 94 may be formed by the use of, for example, a deposition process using a second metal source gas (e.g., titanium, niobium, tantalum, vanadium, and tin), and an oxide source gas (e.g., ozone plasma). Accordingly, the second interface layer 94 may include the second metal oxide.

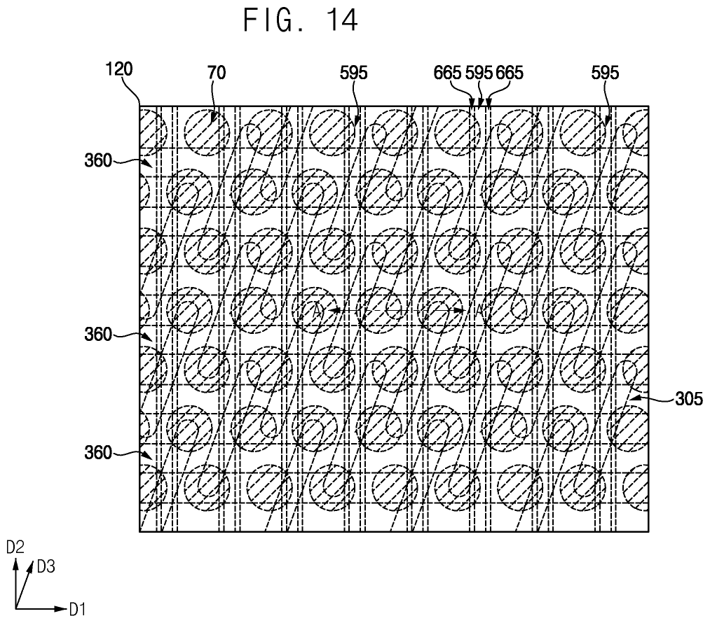

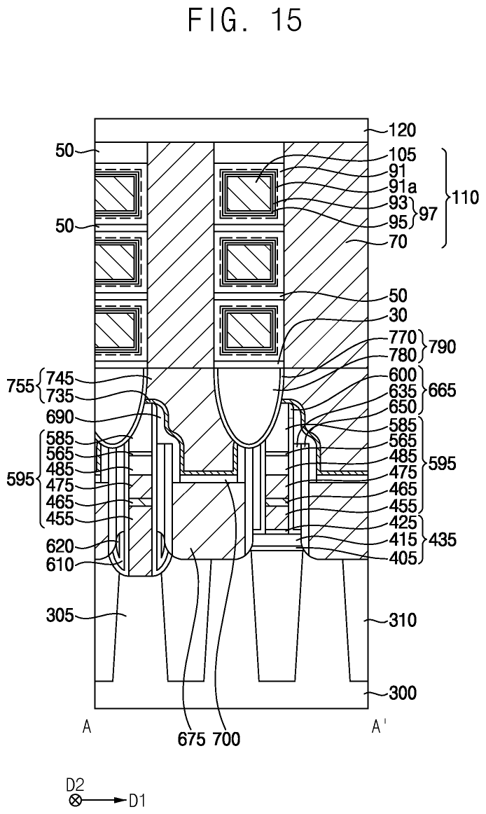

Referring to FIGS. 11 and 12, an upper electrode layer 100 may be formed on the second interface layer 94 to fill remaining portions of the respective third openings 80. Here, the upper electrode layer 100 may be formed by the used of, for example, a deposition process using a metal source gas (e.g., a titanium source gas) and a nitrogen source gas (e.g., ammonia). In some embodiments, this deposition process may be substantially similar to that of the process used to form the lower electrode 70. Accordingly, the upper electrode layer 100 may include a metal nitride, such as titanium nitride.

Referring back to FIGS. 1 and 2, portions of the dielectric layer 90, the preliminary nitrogen including portion 90a, the first and second interface layers 92 and 94 and the upper electrode layer 100 stacked on the upper surfaces of the lower electrode 70 and the uppermost one of the support layers 50 may be removed. Thereafter, portions of the dielectric layer 90, the preliminary nitrogen including portion 90a, the first and second interface layers 92 and 94 and the upper electrode layer 100 remaining in each third opening 80 may respectively constitute the dielectric pattern 91, the nitrogen including portion 91a, first and second interface patterns 93 and 95 and the upper electrode 105, wherein the first and second interface patterns 93 and 95 may be collectively referred to as the “interface structure” 97, and the lower electrode 70, the dielectric pattern 91, the interface structure 97 and the upper electrode 105 may be collectively referred to as the “capacitor” 110.

An upper electrode plate 120 may be formed on the capacitor 110 and may include, for example, doped silicon-germanium.

In this regard, the capacitor structure may be formed using the above-described method. That is, the first preliminary interface layer may be formed on the dielectric layer 90, the heat treatment process and/or the plasma treatment process may be performed on the first preliminary interface layer under a nitrogen atmosphere so that the first preliminary interface layer may be converted to the first interface layer 92 including the first metal oxide doped with nitrogen, and the second interface layer 94 including the second metal oxide may be formed on the first interface layer 92. Accordingly, the interface structure 97 including the first and second interface patterns 93 and 95 may be formed between the dielectric pattern 91 and the upper electrode 105.

The interface structure 97 between the dielectric pattern 91 and the upper electrode 105 may decrease a leakage current of the capacitor 110. In addition, the first interface pattern 93 including the first metal oxide and doped with nitrogen may have a conductivity greater than the first metal oxide. Thus, the first interface pattern 93 between the dielectric pattern 91 and the second interface pattern 95 need not increase a total thickness of a dielectric structure between the lower electrode 70 and the upper electrode 105, and thus a capacitance of the capacitor 110 need not decrease.

FIG. 13 is a graph illustrating leakage current for a comparative, conventional embodiment and an example embodiment of the inventive concept. The x-axis of the graph indicates a percentage of the respective capacitances, and the y-axis indicates a percentage of leakage current.

Referring to FIG. 13, the first capacitor associated with the example embodiment includes an interface structure having a double-layered structure including a first interface pattern including titanium oxide doped with nitrogen and a second interface pattern including titanium oxide, while a second capacitor associated with the comparative, conventional embodiment includes an interface structure having a single-layered structure including titanium oxide and having substantially the same thickness as the interface structure of the embodiment.

As may be noted in relation to FIG. 13, the first capacitor exhibits a greater capacitance than that of the second capacitor in relation to the same leakage current percentage. Accordingly, if an interface structure disposed between a dielectric pattern and an upper electrode of a capacitor has a double-layered structure including an interface pattern including a metal oxide and an interface pattern including a metal oxide doped with nitrogen, the capacitor will provide improved electrical performance characteristics.

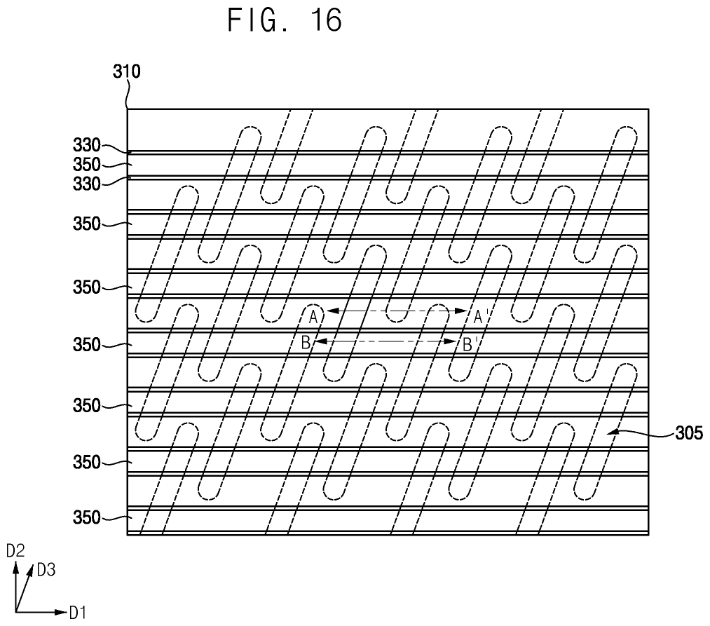

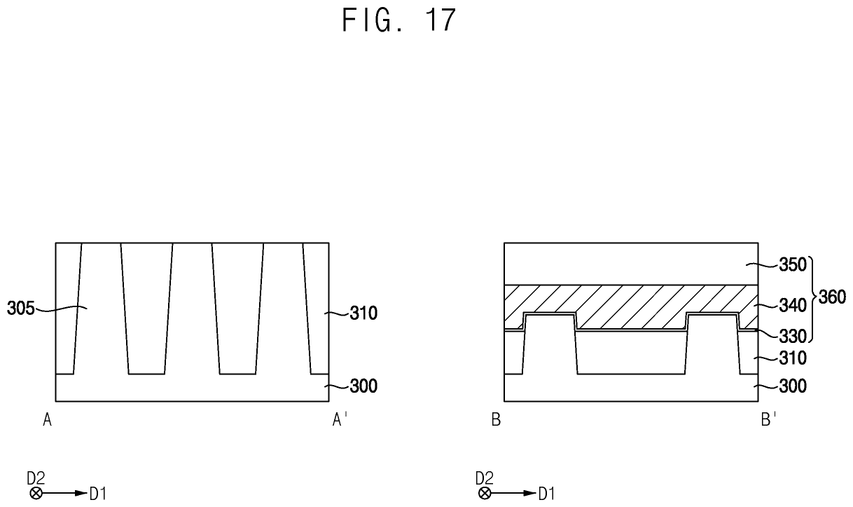

FIG. 14 is a plan view illustrating a semiconductor device according to embodiments of the inventive concept, and FIG. 15 is a cross-sectional view taken along line A-A′ of FIG. 14.

The semiconductor device (e.g., a Dynamic Random Access Memory, or DRAM) of FIGS. 14 and 15 is one example an application including the capacitor structure described in relation to FIGS. 1 and 2.

Hereinafter, first and second horizontal directions (D1 and D2) are assumed to be substantially parallel to an upper surface of a substrate 300 and substantially orthogonal to each other, whereas a third (or vertical) direction (D3) is assumed to be at an acute angle with respect to the first and second horizontal directions D1 and D2 and substantially perpendicular to the upper surface of the substrate 300.

Referring to FIGS. 14 and 15, the semiconductor device may include an active pattern 305, a gate structure 360, a first bit line structure 595, a contact plug structure, and the capacitor structure on the substrate 300.

The semiconductor device may further include an isolation pattern 310, a spacer structure 665, a fourth spacer 690, a second capping pattern 685, first and second insulation pattern structures 435 and 790, fifth and sixth insulation patterns 610 and 620, and a metal silicide pattern 700.

The active pattern 305 may extend in the third direction D3, and a plurality of active patterns 305 may be spaced apart in the first and second horizontal directions D1 and D2. A sidewall of the active pattern 305 may be covered by the isolation pattern 310. The active pattern 305 may include substantially the same material as the substrate 300, and the isolation pattern 310 may include an oxide, such as silicon oxide.

Referring to FIGS. 14, 15 and 17, the gate structure 360 may be formed in a second recess extending in the first horizontal direction D1 through upper portions of the active pattern 305 and the isolation pattern 310. The gate structure 360 may include a first gate insulation pattern 330 on a bottom and a sidewall of the second recess, a first gate electrode 340 on a portion of the first gate insulation pattern 330 on the bottom and a lower sidewall of the second recess, and a gate mask 350 on the first gate electrode 340 and filling an upper portion of the second recess.

The first gate insulation pattern 330 may include an oxide (e.g., silicon oxide), the first gate electrode 340 may include at least one of a metal, a metal nitride, and a metal silicide, and the gate mask 350 may include an insulating nitride (e.g., silicon nitride).

In some embodiments, the gate structure 360 may extend in the first horizontal direction D1, and a plurality of gate structures 360 may be spaced apart in the second horizontal direction D2.

Referring to FIGS. 14, 15, 18 and 19, a fourth opening 440 extending through an insulation layer structure 430 and exposing upper surfaces of the active pattern 305, the isolation pattern 310 and the gate mask 350 of the gate structure 360 may be formed, and an upper surface of a central portion in the third direction D3 of the active pattern 305 may be exposed by the fourth opening 440.

In some embodiments, an area of a bottom of the fourth opening 440 may be greater than an area of the upper surface of the active pattern 305. Thus, the fourth opening 440 may also expose an upper surface of a portion of the isolation pattern 310 adjacent to the active pattern 305. Additionally, the fourth opening 440 may extend through upper portions of the active pattern 305 and the portion of the isolation pattern 310 adjacent thereto, and thus the bottom of the fourth opening 440 may be lower than an upper surface of each of opposite edge portions in the third direction D3 of the active pattern 305.

The first bit line structure 595 may include a second conductive pattern 455, a first barrier pattern 465, a third conductive pattern 475, a first mask 485, a second etch stop pattern 565 and a first capping pattern 585 sequentially stacked in the vertical direction on the fourth opening 440 or the first insulation pattern structure 435. The second conductive pattern 455, the first barrier pattern 465 and the third conductive pattern 475 may collectively form a conductive structure, and the first mask 485, the second etch stop pattern 565 and the first capping pattern 585 may collectively form an insulation structure.

The second conductive pattern 455 may include, for example, doped polysilicon. The first barrier pattern 465 may include a metal nitride (e.g., titanium nitride, or a metal silicon nitride, such as titanium silicon nitride. The third conductive pattern 475 may include a metal (e.g., tungsten), and each of the first mask 485, the second etch stop pattern 565 and the first capping pattern 585 may include an insulating nitride (e.g., silicon nitride).

In some embodiments, the first bit line structure 595 may extend in the second horizontal direction D2 on the substrate 300, and a plurality of first bit line structures 595 may be spaced apart in the first horizontal direction D1.

The fifth and sixth insulation patterns 610 and 620 may be formed in the fourth opening 440, and may contact a lower sidewall of the first bit line structure 595. The fifth insulation pattern 610 may include an oxide, e.g., silicon oxide, and the sixth insulation pattern 620 may include an insulating nitride, e.g., silicon nitride.

The first insulation pattern structure 435 may be formed on the active pattern 305 and the isolation pattern 310 under the first bit line structure 595, and may include second, third and fourth insulation patterns 405, 415 and 425 sequentially stacked in the vertical direction. The second and fourth insulation patterns 405 and 425 may include an oxide (e.g., silicon oxide), and the third insulation pattern 415 may include an insulating nitride (e.g., silicon nitride).

The contact plug structure may include a lower contact plug 675, a metal silicide pattern 700 and an upper contact plug 755 sequentially stacked in the third direction D3 on the active pattern 305 and the isolation pattern 310.

The lower contact plug 675 may contact the upper surface of each of opposite edge portions in the third direction D3 of the active pattern 305. In some embodiments, a plurality of lower contact plugs 675 may be spaced apart in the second horizontal direction D2 between neighboring ones of the first bit line structures 595 in the first horizontal direction D1, and a second capping pattern 685 may be formed between neighboring ones of the lower contact plugs 675 in the second horizontal direction D2. The second capping pattern 685 may include an insulating nitride (e.g., silicon nitride).

The lower contact plug 675 may include, for example, doped polysilicon, and the metal silicide pattern 700 may include at least one of for example, titanium silicide, cobalt silicide, and nickel silicide.

The upper contact plug 755 may include a second metal pattern 745 and a second barrier pattern 735 covering a lower surface of the second metal pattern 745. The second metal pattern 745 may include a metal (e.g., tungsten), and the second barrier pattern 735 may include a metal nitride (e.g., titanium nitride).

In some embodiments, a plurality of upper contact plugs 755 may be spaced apart in the first and second directions D1 and D2, and may be disposed in a honeycomb pattern or a lattice pattern. The upper contact plugs 755 may have an elliptical shape, a circular shape, and/or a polygonal shape.

The spacer structure 665 may include a first spacer 600 covering sidewalls of the first bit line structure 595 and the fourth insulation pattern 425, an air spacer 635 on a lower outer sidewall of the first spacer 600, and a third spacer 650 on an outer sidewall of the air spacer 635, a sidewall of the first insulation pattern structure 435, and upper surfaces of the fifth and sixth insulation patterns 610 and 620.

Each of the first and third spacers 600 and 650 may include an insulating nitride (e.g., silicon nitride) and the air spacer 895 may include air.

The fourth spacer 690 may be formed on an outer sidewall of a portion of the first spacer 600 on an upper sidewall of the first bit line structure 595, and may cover an upper end of the air spacer 635 and an upper surface of the third spacer 650. The fourth spacer 690 may include an insulating nitride (e.g., silicon nitride).

Referring to FIGS. 14, 15 30 and 31, the second insulation pattern structure 790 may include a seventh insulation pattern 770 on an inner wall of a ninth opening 760, which may extend through the upper contact plug 755, a portion of the insulation structure of the first bit line structure 595 and portions of the first, third and fourth spacers 600, 650 and 690 and surround the upper contact plug 755, and an eighth insulation pattern 780 on the seventh insulation pattern 770 and filling a remaining portion of the ninth opening 760. The upper end of the air spacer 635 may be closed by the seventh insulation pattern 770.

The seventh and eighth insulation patterns 770 and 780 may include an insulating nitride (e.g., silicon nitride).

The first etch stop layer 30 may be formed on the seventh and eighth insulation patterns 770 and 780, the upper contact plug 755 and the second capping pattern 685.

The capacitor 110 may contact an upper surface of the upper contact plug 755.

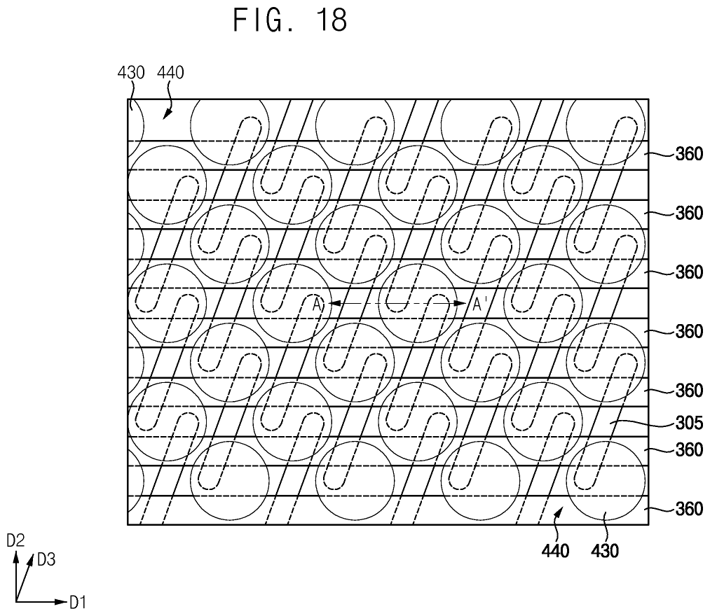

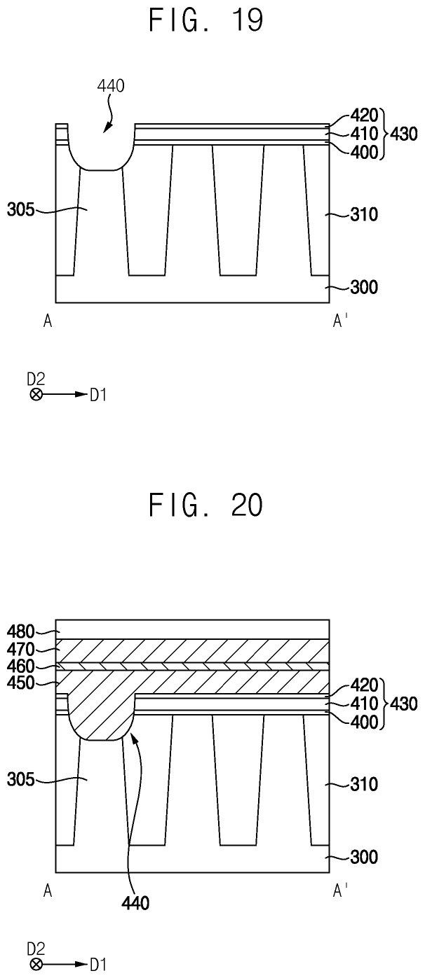

FIGS. 16 to 31 are related views illustrating in one example a method of manufacturing a semiconductor device according to embodiments of the inventive concept, wherein FIGS. 16, 18, 21, 25 and 29 are respective plan views and FIGS. 17, 19, 20, 22, 23, 26, 27, 28, 30 and 31 are respective cross-sectional views taken along one of lines A-A′ and B-B′ in a corresponding plan view.

The method of manufacturing semiconductor devices described in FIGS. 16 to 31 is drawn to one possible application related to a DRAM including the capacitor structure described in relation to FIGS. 1, 2, 3, 4, 5 and 6.

Referring to FIGS. 16 and 17, an upper portion of a substrate 300 may be removed to form a first recess, and an isolation pattern 310 may be formed in the first recess.

As the isolation pattern 310 is formed on the substrate 300, an active pattern 305 of which a sidewall is covered by the isolation pattern 310 may be defined.

The active pattern 305 and the isolation pattern 310 on the substrate 300 may be partially etched to form a second recess extending in the first horizontal direction D1, and a gate structure 360 may be formed in the second recess. In some embodiments, the gate structure 360 may extend in the first horizontal direction D1, and a plurality of gate structures may be spaced apart in the second horizontal direction D2.

Referring to FIGS. 18 and 19, an insulation layer structure 430 may be formed on the active pattern 305, the isolation pattern 310, and the gate structure 360. The insulation layer structure 430 may include second to fourth insulation layers 400, 410, and 420 sequentially stacked.

The insulation layer structure 430 may be patterned, and the active pattern 305, the isolation pattern 310, and the gate mask 350 included in the gate structure 360 may be partially etched using the patterned insulation layer structure 430 as an etching mask to form a fourth opening 440. In some embodiments, the insulation layer structure 430 may have a circular shape or an elliptical shape, and a plurality of insulation layer structures 430 may be spaced apart in the first and second horizontal direction D1 and D2. Each of the insulation layer structures 430 may overlap end portions of ones of the active patterns 305 neighboring in the third direction D3, which may face each other in the third direction D3.

Referring to FIG. 20, a first conductive layer 450, a first barrier layer 460, a second conductive layer 470 and a first mask layer 480 may be sequentially stacked on the insulation layer structure 430, and the active pattern 305, the isolation pattern 310 and the gate structure 360 exposed by the fourth opening 440, which may collectively form a conductive structure layer. The first conductive layer 450 may fill the fourth opening 440.

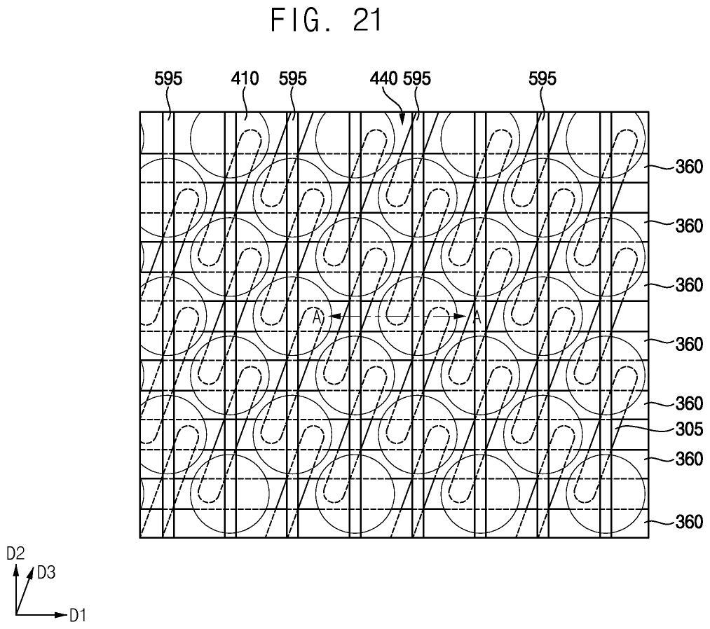

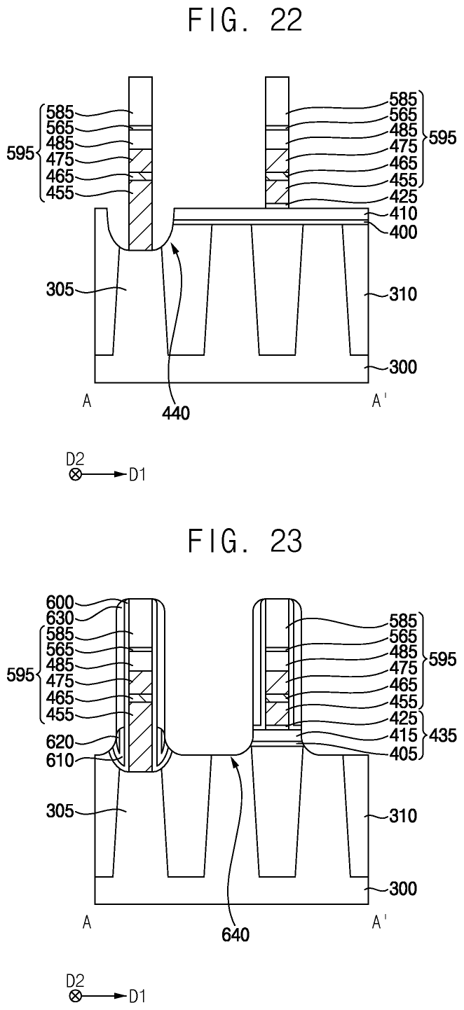

Referring to FIGS. 21 and 22, a second etch stop layer and a first capping layer may be sequentially formed on the conductive structure layer, the first capping layer may be etched to form a first capping pattern 585, and the second etch stop layer, the first mask layer 480, the second conductive layer 470, the first barrier layer 460 and the first conductive layer 450 may be sequentially etched using the first capping pattern 585 as an etch mask.

In some embodiments, the first capping pattern 585 may extend in the second horizontal direction D2, and a plurality of first capping patterns 585 may be spaced apart in the first horizontal direction D1.

By the etching process, a second conductive pattern 455, a first barrier pattern 465, a third conductive pattern 475, a first mask 485, a second etch stop pattern 565 and the first capping pattern 585 may be formed on the fourth opening 440, and a fourth insulation pattern 425, the second conductive pattern 455, the first barrier pattern 465, the third conductive pattern 475, the first mask 485, the second etch stop pattern 565 and the first capping pattern 585 may be sequentially stacked on the third insulation layer 410 of the insulation layer structure 430 at an outside of the fourth opening 440.

Hereinafter, the second conductive pattern 455, the first barrier pattern 465, the third conductive pattern 475, the first mask 485, the second etch stop pattern 565 and the first capping pattern 585 sequentially stacked may be referred to as a first bit line structure 595. The second conductive pattern 455, the first barrier pattern 465 and the third conductive pattern 475 may form a conductive structure, and the first mask 485, the second etch stop pattern 565 and the first capping pattern 585 may form an insulation structure. In some embodiments, the first bit line structure 595 may extend in the second horizontal direction D2, and a plurality of first bit line structures 595 may be spaced apart in the first horizontal direction D1.

Referring to FIG. 23, a first spacer layer may be formed on the substrate 300 on which the first bit line structure 595 is formed, and fifth and sixth insulation layers may be sequentially formed on the first spacer layer.

The first spacer layer may also cover a sidewall of the fourth insulation pattern 425 under the first bit line structure 595 on the third insulation layer 410, and the sixth insulation layer may fill a remaining portion of the fourth opening 440.

The fifth and sixth insulation layers may be etched by an etching process. In some embodiments, the etching process may be a wet etching process using, for example, phosphoric acid (H₂PO₃), SC1, and hydrofluoric acid (HF) as an etchant, and portions of the fifth and sixth insulation layers except for portions thereof in the fourth opening 440 may be removed. Accordingly, most portions of a surface of the first spacer layer, that is, all portions of the surface of the first spacer layer except for a portion of the surface thereof in the fourth opening 440 may be exposed, and the fifth and sixth insulation layers remaining in the fourth opening 440 may form fifth and sixth insulation patterns 610 and 620, respectively.

A second spacer layer may be formed on the exposed surface of the first spacer layer and the fifth and sixth insulation patterns 610 and 620 in the fourth opening 440. The second spacer layer may be anisotropically etched to form a second spacer 630 covering a sidewall of the first bit line structure 595 on the surface of the first spacer layer and on the fifth and sixth insulation patterns 610 and 620.

A dry etching process may be performed using the first capping pattern 585 and the second spacer 630 as an etch mask to form a fifth opening 640 exposing an upper surface of the active pattern 305, and upper surfaces of the isolation pattern 310 and the gate mask 350 may also be exposed by the fifth opening 640.

By the dry etching process, portions of the first spacer layer on upper surfaces of the first capping pattern 585 and the second insulation layer 410 may be removed, and thus a first spacer 600 may be formed on the sidewall of the first bit line structure 595. By the dry etching process, the second and third insulation layers 400 and 410 may be partially removed to remain as second and third insulation patterns 405 and 415, respectively, under the first bit line structure 595. The second to fourth insulation patterns 405, 415 and 425 sequentially stacked under the first bit line structure 595 may form a first insulation pattern structure 435.

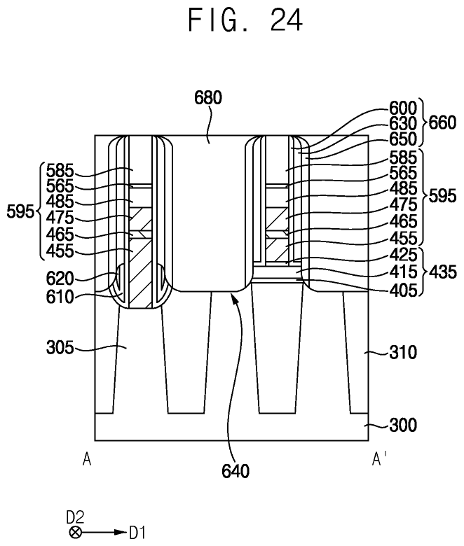

Referring to FIG. 24, a third spacer layer may be formed on an upper surface of the first capping pattern 585, an outer sidewall of the second spacer 630, portions of the upper surfaces of the fifth and sixth insulation patterns 610 and 620, and the upper surfaces of the active pattern 305, the isolation pattern 310 and the gate mask 350 exposed by the fifth opening 640. The third spacer layer may be anisotropically etched to form a third spacer 650 covering the sidewall of the first bit line structure 595.

The first to third spacers 600, 630 and 650 sequentially stacked on the sidewall of the first bit line structure 595 in at least one of the first and second horizontal directions may be referred to as a preliminary spacer structure 660.

A second sacrificial layer may be formed to fill the fifth opening 640 on the substrate 300 to a sufficient height, and an upper portion of the second sacrificial layer may be planarized until the upper surface of the first capping pattern 585 is exposed to form a second sacrificial pattern 680 in the fifth opening 640.

In some embodiments, the second sacrificial pattern 680 may extend in the second horizontal direction D2, and a plurality of second sacrificial patterns 680 may be spaced apart in the first horizontal direction D1 by the first bit line structures 595. The second sacrificial pattern 680 may include, for example, an oxide, such as silicon oxide.

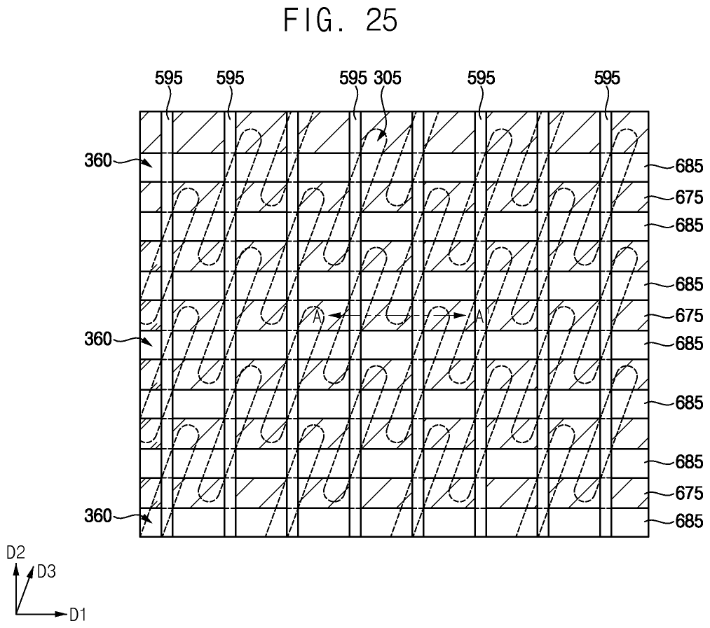

Referring to FIGS. 25 and 26, a second mask including a plurality of sixth openings, each of which may extend in the first horizontal direction D1, spaced apart in the second horizontal direction D2 may be formed on the first capping pattern 585, the second sacrificial pattern 680 and the preliminary spacer structure 660, and may be etched using the second mask as an etching mask.

In some embodiments, each of the sixth openings may overlap a region between the gate structures 360 in the vertical direction. By the etching process, a seventh opening exposing the upper surfaces of the active pattern 305 and the isolation pattern 310 may be formed between the first bit line structures 595 on the substrate 300.

The second mask may be removed, a lower contact plug layer may be formed to fill the seventh opening to a sufficient height, and an upper portion of the lower contact plug layer may be planarized until the upper surface of the first capping pattern 585 and upper surfaces of the second sacrificial pattern 680 and the preliminary spacer structure 660 are exposed. Thus, the lower contact plug layer may be transformed into a plurality of lower contact plugs 675 spaced apart in the second horizontal direction D2 between the first bit line structures 595. Additionally, the second sacrificial pattern 680 extending in the second horizontal direction D2 between the first bit line structures 595 may be divided into a plurality of parts in the second horizontal direction D2 by the lower contact plugs 675.

The second sacrificial pattern 680 may be removed to form an eighth opening, and a second capping pattern 685 may be formed to fill the eighth opening. In some embodiments, the second capping pattern 685 may overlap the gate structure 360 in the vertical direction.

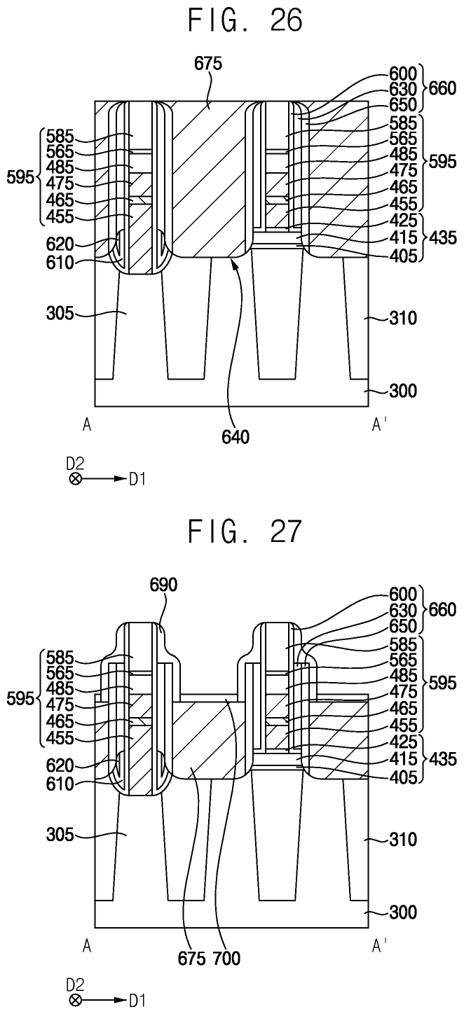

Referring to FIG. 27, an upper portion of the lower contact plug 675 may be removed to expose an upper portion of the preliminary spacer structure 660 on the sidewall of the first bit line structure 595, and upper portions of the second and third spacers 630 and 650 of the exposed preliminary spacer structure 660 may be removed.

An upper portion of the lower contact plug 675 may be additionally removed. Thus, an upper surface of the lower contact plug 675 may be lower than upper surfaces of the second and third spacers 630 and 650.

A fourth spacer layer may be formed on the first bit line structure 595, the preliminary spacer structure 660, the second capping pattern 685 and the lower contact plug 675, and may be anisotropically etched to form a fourth spacer 690 covering an upper portion of the preliminary spacer structure 660 on the sidewall of the first bit line structure 595, and the upper surface of the lower contact plug 675 may be exposed by the etching process.

A metal silicide pattern 700 may be formed on the exposed upper surface of the lower contact plug 675. In some embodiments, the metal silicide pattern 700 may be formed by forming a first metal layer on the first and second capping patterns 585 and 685, the fourth spacer 690 and the lower contact plug 675, performing a heat treatment thereon, and removing an unreacted portion of the first metal layer.

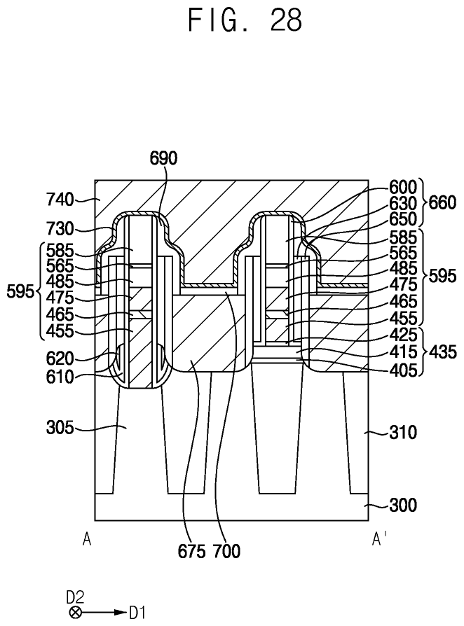

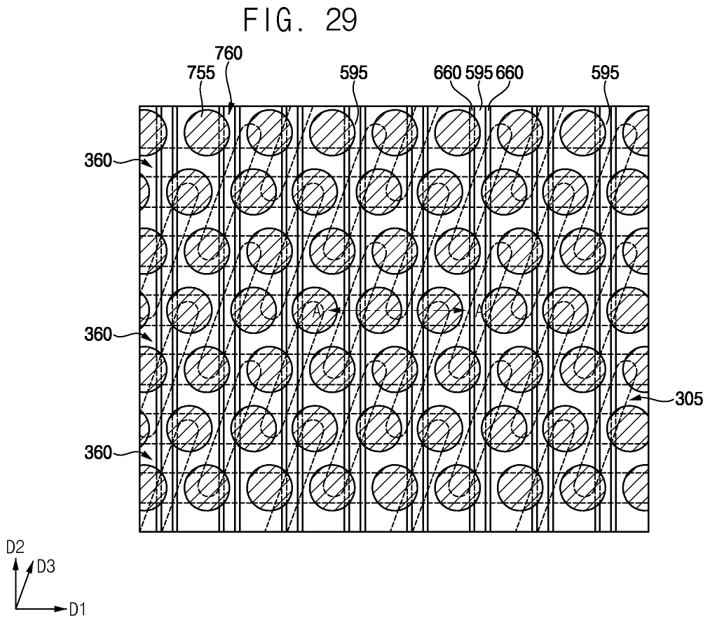

Referring to FIG. 28, a second barrier layer 730 may be formed on the first and second capping patterns 585 and 685, the fourth spacer 690, the metal silicide pattern 700 and the lower contact plug 675, and a second metal layer 740 may be formed on the second barrier layer 730 to fill a space between the first bit line structures 595.

A planarization process may be performed on an upper portion of the second metal layer 740, wherein the planarization process may include at least one of a CMP process and an etch-back process.

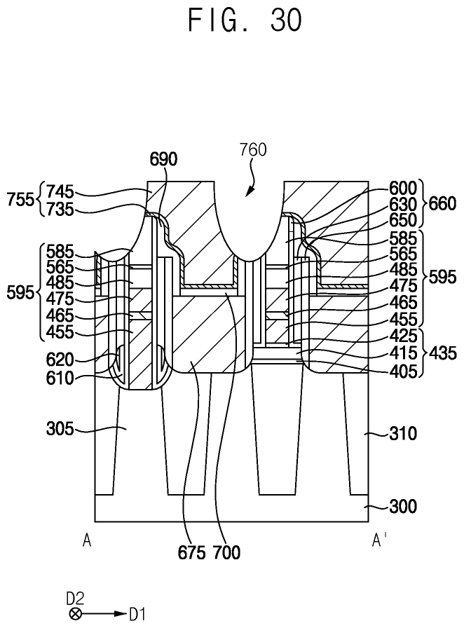

Referring to FIGS. 29 and 30, the second metal layer 740 and the second barrier layer 730 may be patterned to form an upper contact plug 755. In some embodiments, a plurality of upper contact plugs 755 may be formed, and a ninth opening 760 may be formed between the upper contact plugs 755.

The ninth opening 760 may be formed by partially removing the first and second capping patterns 585 and 685, the preliminary spacer structure 660 and the fourth spacer 690 as well as the second metal layer 740 and the second barrier layer 730.

The upper contact plug 755 may include a second metal pattern 745 and a second barrier pattern 735 covering a lower surface of the second metal pattern 745. In some embodiments, the upper contact plug 755 may have a shape of a circle, an ellipse, or a rounded polygon, and the upper contact plugs 755 may be disposed, for example, in a honeycomb pattern extending in the first and second horizontal directions D1 and D2.

The lower contact plug 675, the metal silicide pattern 700 and the upper contact plug 755 sequentially stacked on the substrate 300 may collectively form a contact plug structure.

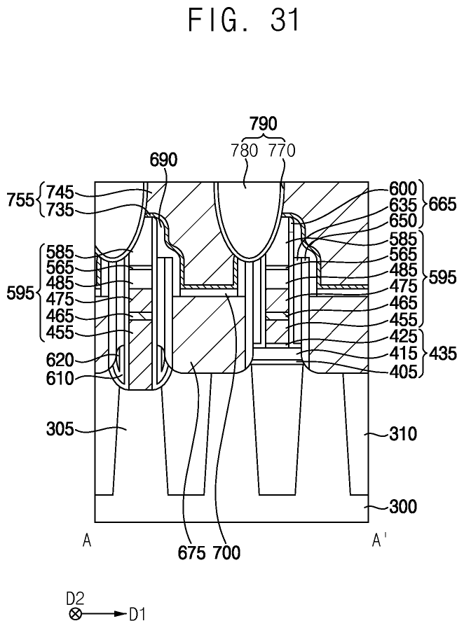

Referring to FIG. 31, the second spacer 630 included in the preliminary spacer structure 660 exposed by the ninth opening 760 may be removed to form an air gap, a seventh insulation pattern 770 may be formed on a bottom and a sidewall of the ninth opening 760, and an eighth insulation pattern 780 may be formed to fill a remaining portion of the ninth opening 760.

Each of the seventh and eighth insulation patterns 770 and 780 may form a second insulation pattern structure 790.

An upper end of the air gap may be covered by the seventh insulation pattern 770, and thus an air spacer 635 may be formed. The first spacer 600, the air spacer 635 and the third spacer 650 may form a spacer structure 665.

Referring back to FIGS. 14 and 15, the capacitor 110, the first etch stop layer 30, the support layer 50 and the upper electrode plate 120 may be formed by processes substantially the same as or similar to the processes described with reference to FIGS. 1 to 12.

The lower electrode 70 included in the capacitor 110 may contact an upper surface of the upper contact plug 755.

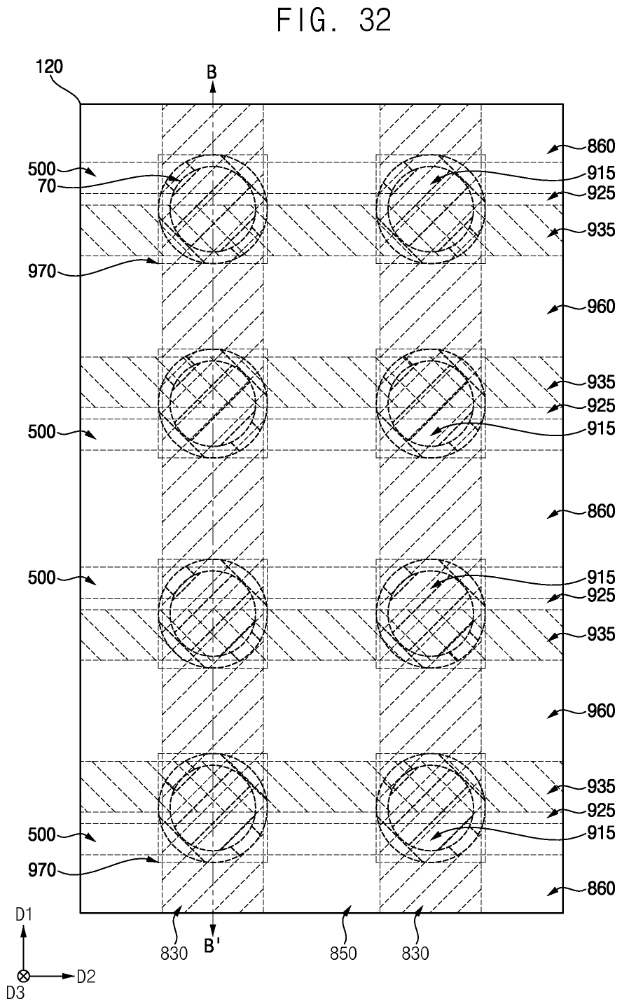

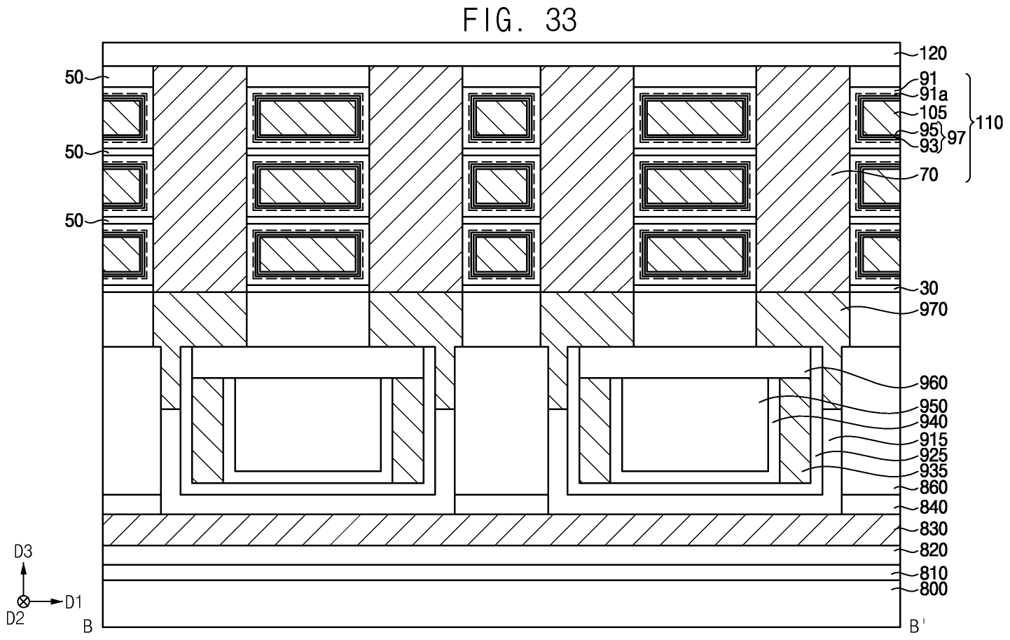

FIG. 32 is a plan view and FIG. 33 is a cross-sectional view collectively illustrating a semiconductor device according to embodiments of the inventive concept, wherein FIG. 33 is a cross-sectional view taken along line B-B′ of FIG. 32. Here, the exemplary semiconductor device of FIGS. 32 and 33 is a Vertical Channel Transistor (VCT) DRAM.

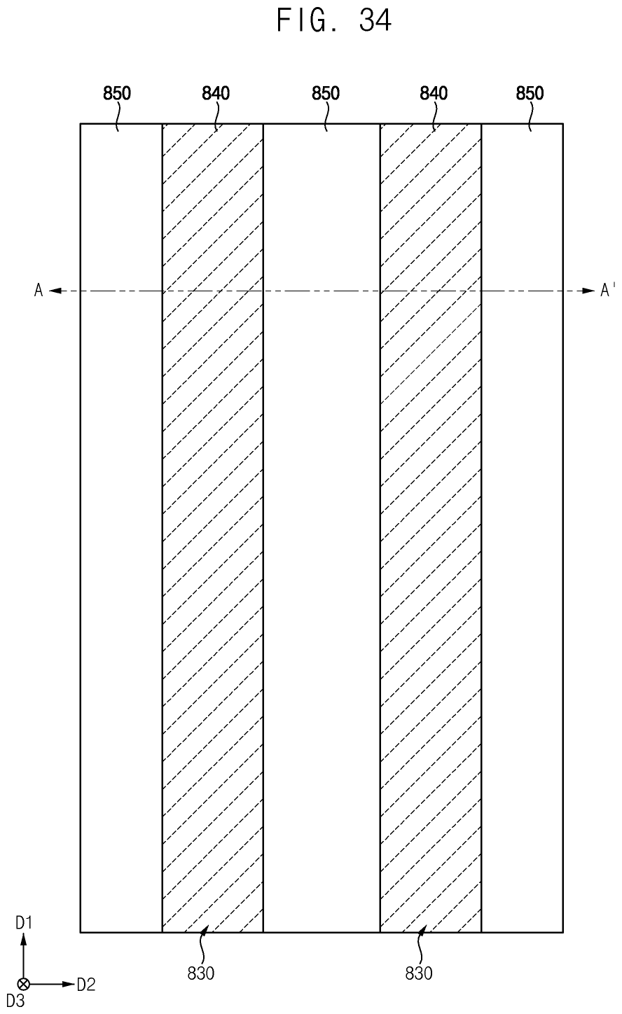

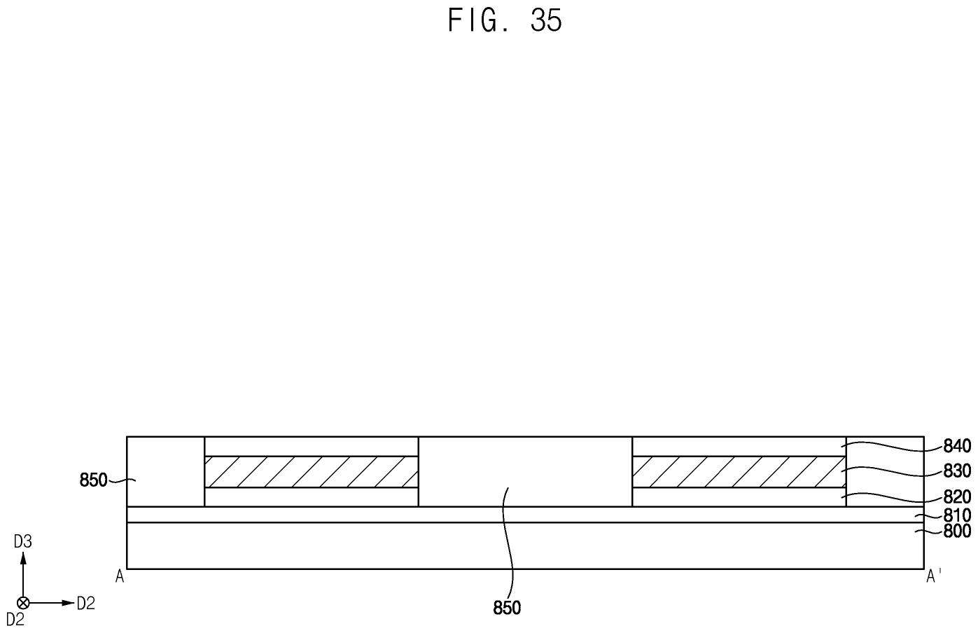

FIGS. 34 to 44 are related views illustrating in one example a method of manufacturing the semiconductor device of FIGS. 32 and 33 according to embodiments of the inventive concept.

Referring to FIGS. 32 and 33, the semiconductor device may include a second bit line structure, a second gate electrode 935, a second gate insulation pattern 925, a channel 915, a contact plug 970 and the capacitor structure on a substrate 800.

The semiconductor device may further include a ninth insulation layer 810, twelfth and thirteenth insulation patterns 940 and 960, and second to fifth insulating interlayer patterns 850, 860, 950 and 980.

The substrate 800 may include, for example, a semiconductor material, an insulation material and/or conductive material.

Referring to FIGS. 32, 33, 34 and 35, the ninth insulation layer 810 may be formed on the substrate 800, and the second bit line structure may extend in the first horizontal direction D1 on the ninth insulation layer 810.

In some embodiments, the second bit line structure may include a tenth insulation pattern 820, a second bit line 830 and an eleventh insulation pattern 840 sequentially stacked on the ninth insulation layer 810. Each of the tenth insulation pattern 820 and the second bit line 830 may extend in the first horizontal direction D1, and a plurality of eleventh insulation patterns 840 may be spaced apart in the first horizontal direction D1 on the second bit line 830.

In some embodiments, a plurality of second bit line structures may be spaced apart in the second horizontal direction D2, and the second insulating interlayer pattern 850 may extend in the first horizontal direction D1 on the ninth insulation layer 810 between neighboring ones of the second bit line structures in the second horizontal direction D2.

An upper surface of a portion of the second insulating interlayer pattern 850 that is adjacent to the eleventh insulation pattern 840 in the second horizontal direction D2 may be substantially coplanar with an upper surface of the eleventh insulation pattern 840, and an upper surface of a portion of the second insulating interlayer pattern 850 that is not adjacent to the eleventh insulation pattern 840 in the second horizontal direction D2 may be substantially coplanar with an upper surface of the second bit line 830. That is, a height of the upper surface of the second insulating interlayer pattern 850 may periodically change in the first horizontal direction D1.

Each of the ninth insulation layer 810 and the second insulating interlayer pattern 850 may include an oxide (e.g., silicon oxide), the second bit line 830 may include a conductive material (e.g., a metal, a metal nitride, and/or a metal silicide), and each of the tenth and eleventh insulation patterns 820 and 840 may include an insulating nitride (e.g., silicon nitride).

The third insulating interlayer pattern 860 extending in the second horizontal direction D2 may be formed on the eleventh insulation pattern 840 and the second insulating interlayer pattern 850. The third insulating interlayer pattern 860 may include an oxide (e.g., silicon oxide). Hereinafter, the third insulation pattern 860, the eleventh insulation pattern 840 thereunder and an upper portion of the second insulating interlayer pattern 850 at the same height as the eleventh insulation pattern 840 may be collectively referred to as a bar structure. In some embodiments, the bar structure may extend in the second horizontal direction D2, and a plurality of bar structures may be spaced apart in the first horizontal direction D1.

In some embodiments, the channel 915 may be formed between neighboring ones of the bar structures in the first horizontal direction D1, and a plurality of channels 915 may be spaced apart in the second horizontal direction D2 on the second bit line 830 and the second insulating interlayer pattern 850. A fourteenth insulation pattern 500 may be formed between neighboring ones of the channels 915 in the second horizontal direction D2. The fourteenth insulation pattern 500 may include an oxide (e.g., silicon oxide) or an insulating nitride (e.g., silicon nitride).

Additionally, a plurality of channels 915 may be spaced apart in the first horizontal direction D1 on the second bit line 830 extending in the first horizontal direction D1. As shown in FIG. 33, a width in the second horizontal direction D2 of the channel 915 may be substantially the same as a width in the second horizontal direction D2 of the second bit line 830, however, the inventive concept may not be limited thereto.

In some embodiments, the channel 915 may be conformally formed on an upper surface of the second bit line 830, an upper surface of the second insulating interlayer pattern 850 and a sidewall of the bar structure, and thus a cross-section of the channel 915 in the first horizontal direction D1 may have a cup shape.

In some embodiments, the channel 915 may include an oxide semiconductor material, wherein the oxide semiconductor material may include at least one of zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓOyN_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), and indium gallium silicon oxide (InGaSiO).

In some embodiments, the channel 915 may include an amorphous oxide semiconductor material. In some embodiments, an upper surface of the channel 915 may be lower than an upper surface of the bar structure.

The fourth insulating interlayer pattern 950 may extend on a portion of the channel 915 on the second bit line 830 and the second insulating interlayer pattern 850 between neighboring ones of the bar structures in the first horizontal direction D1, and a lower surface and a sidewall of the fourth insulating interlayer pattern 950 may be covered by the twelfth insulation pattern 940. A cross-section of the twelfth insulation pattern 940 in the first horizontal direction D1 may have a cup shape, and may contact an upper surface of the portion of the channel 915 on the second bit line 830 and the second insulating interlayer pattern 850.

The fourth insulating interlayer pattern 950 may include an oxide (e.g., silicon oxide), and the twelfth insulation pattern 940 may include an insulating nitride (e.g., silicon nitride).

The second gate insulation pattern 925 and the second gate electrode 935 may be formed between a portion of the channel 915 on the sidewall of the bar structure and the twelfth insulation pattern 940.

The second gate electrode 935 may contact an outer sidewall of the twelfth insulation pattern 940, and may extend in the second horizontal direction D2. An upper surface of the second gate electrode 935 may be substantially coplanar with upper surfaces of the fourth insulating interlayer pattern 950 and the twelfth insulation pattern 940. The second gate electrode 935 may include a conductive material (e.g., a metal, a metal nitride, and/or a metal silicide).

The second gate insulation pattern 925 may extend in the second horizontal direction D2, and may contact a lower surface and an outer sidewall of the second gate electrode 935. Additionally, the second gate insulation pattern 925 may contact inner sidewalls of the portion of the channel 915 and a lower portion of the contact plug 970 on the sidewall of the bar structure, and an upper surface of the portion of the channel 915 on the second bit line 830 and the second insulating interlayer pattern 850. Thus, a cross-section of the second gate insulation pattern 925 in the first horizontal direction D1 may have an ‘L’ shape.

The second gate insulation pattern 925 may include a metal oxide (e.g., aluminum oxide, hafnium oxide, and/or zirconium oxide), or silicon oxide.

The thirteenth insulation pattern 960 may be formed on the fourth insulating interlayer pattern 950, the twelfth insulation pattern 940 and the second gate electrode 935, and may extend in the second horizontal direction D2. The thirteenth insulation pattern 960 may contact the upper surfaces of the fourth insulating interlayer pattern 950, the twelfth insulation pattern 940 and the second gate electrode 935, and an upper inner sidewall of the second gate insulation pattern 925.

In some embodiments, an upper surface of the thirteenth insulation pattern 960 may be substantially coplanar with the upper surface of the second gate insulation pattern 925. The thirteenth insulation pattern 960 may include an insulating nitride (e.g., silicon nitride).

The contact plug 970 may contact the upper surface of the channel 915 at each of areas where the second bit lines 830 and the second gate electrodes 935 cross each other in the third direction D3. The contact plug 970 may contact the upper surfaces of the second gate insulation pattern 925, the third insulating interlayer pattern 860 and the thirteenth insulation pattern 960 adjacent to the channel 915, and may be spaced apart from the upper surface of the second gate electrode 935 by the thirteenth insulation pattern 960.

In some embodiments, the contact plug 970 may include the lower portion contacting the upper surface of the channel 915, and an upper portion on the lower portion and having a width greater than a width of the lower portion. The lower portion of the contact plug 970 may contact the second gate insulation pattern 925 and the third insulating interlayer pattern 860, and a lower surface of the lower portion of the contact plug 970 may be lower than an upper surface of the second gate electrode 935.

In some embodiments, a plurality of contact plugs 970 may be spaced apart in the first and second horizontal directions D1 and D2, and may be extend in a lattice pattern or a honeycomb pattern. The contact plug 970 may include a conductive material (e.g., a metal, a metal nitride, and/or a metal silicide).

The fifth insulating interlayer pattern 980 may be formed on the third insulating interlayer pattern 860, the channel 915, the second gate insulation pattern 925 and the thirteenth insulation pattern 960, and may cover a sidewall of the contact plug 970. The fifth insulating interlayer pattern 980 may include an oxide (e.g., silicon oxide).

The lower electrode 70 included in the capacitor 110 may contact an upper surface of the contact plug 970. As the contact plugs 970 are spaced apart in the first and second horizontal directions D1 and D2, a plurality of lower electrode 70 may be spaced apart in the first and second horizontal directions D1 and D2.

In the semiconductor device, current may flow in the third direction D3, that is, in the vertical direction in the channel 915 between the second bit line 830 and the contact plug 970, and thus the semiconductor device may include a vertical channel transistor (VCT) having a vertical channel.

Hereinafter, first and second horizontal directions (D1 and D2) are assumed to be substantially parallel to an upper surface of a substrate 800 and substantially orthogonal to each other, whereas a third (or vertical) direction (D3) is assumed to be at an acute angle with respect to the first and second horizontal directions D1 and D2 and substantially perpendicular to the upper surface of the substrate 800.

Referring to FIGS. 34 and 35, a ninth insulation layer 810, a tenth insulation layer, a second bit line layer and an eleventh insulation layer may be sequentially stacked on a substrate 800, and the eleventh insulation layer, the second bit line layer and the tenth insulation layer may be patterned to form a eleventh insulation pattern 840, a second bit line 830 and a tenth insulation pattern 820, respectively.

The tenth insulation pattern 820, the second bit line 830 and the eleventh insulation pattern 840 sequentially stacked on the substrate 800 may be referred to as a second bit line structure. In some embodiments, the second bit line structure may extend in the first horizontal direction D1 on the substrate 800, and a plurality of second bit line structures may be spaced apart in the second horizontal direction D2. Thus, a tenth opening may be formed between neighboring ones of the second bit line structures in the second horizontal direction D2 to expose an upper surface of the ninth insulation layer 810.

A second insulating interlayer may be formed on the second bit line structures and the ninth insulation layer 810 to fill the tenth opening, and an upper portion of the second insulating interlayer may be planarized until upper surfaces of the second bit line structures are exposed. Thus, a second insulating interlayer pattern 850 extending in the first horizontal direction D1 may be formed on the ninth insulation layer 810 between the second bit line structures.

In some embodiments, the planarization process may include a chemical mechanical polishing (CMP) process and/or an etch back process.

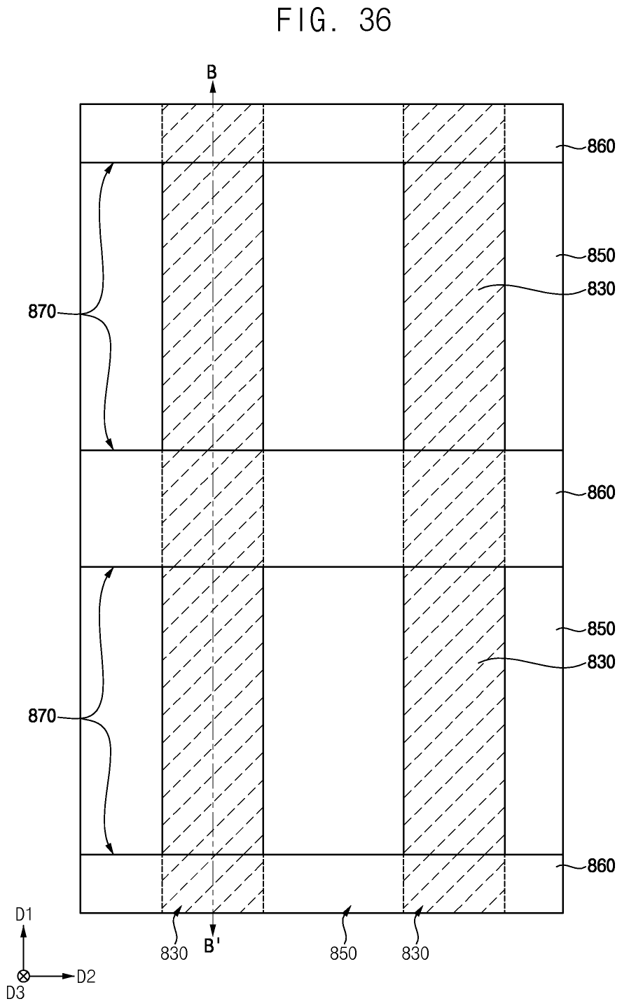

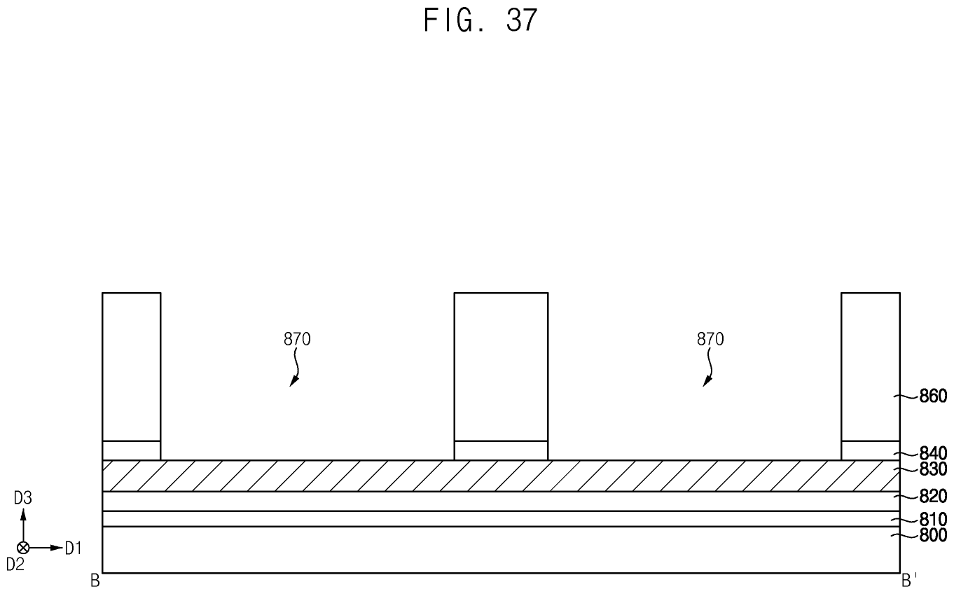

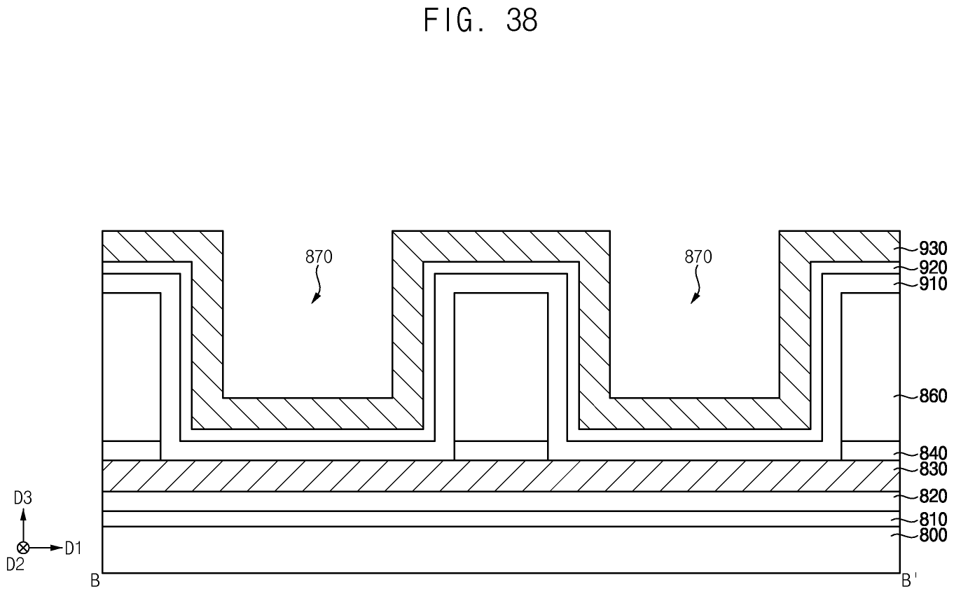

Referring to FIGS. 36 and 37, a third insulating interlayer may be formed on the second bit line structures and the second insulating interlayer patterns 850, and the third insulating interlayer and the eleventh insulation pattern 840 may be partially removed by, e.g., a dry etching process to form an eleventh opening 870 extending in the second horizontal direction D2 and exposing upper surfaces of the second bit line 830 and the second insulating interlayer pattern 850.

Thus, the third insulating interlayer may be divided into a plurality of third insulating interlayer patterns 860, each of which may extend in the second horizontal direction D2, spaced apart in the first horizontal direction D1.

Referring to FIG. 38, a channel layer 910, a second gate insulation layer 920 and a second gate electrode layer 930 may be sequentially stacked on upper surfaces of the second bit line 830 and the second insulating interlayer pattern 850 exposed by the tenth opening 870 and a sidewall and an upper surface of the third insulating interlayer pattern 860.

In some embodiments, the channel layer 910, the second gate insulation layer 920 and the second gate electrode layer 930 may be formed by a deposition process, e.g., an ALD process, a CVD process, etc.

In some embodiments, the channel layer 910 may include an amorphous oxide semiconductor material, e.g., IGZO, and may be formed at a relatively low temperature. The second gate insulation layer 920 and the second gate electrode layer 930 may be formed at a relatively high temperature.

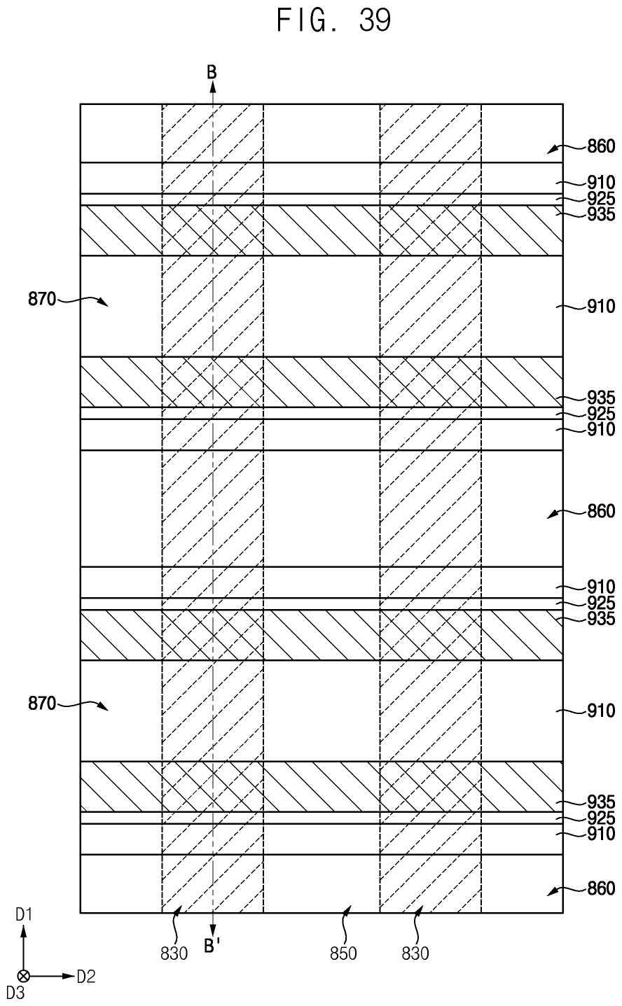

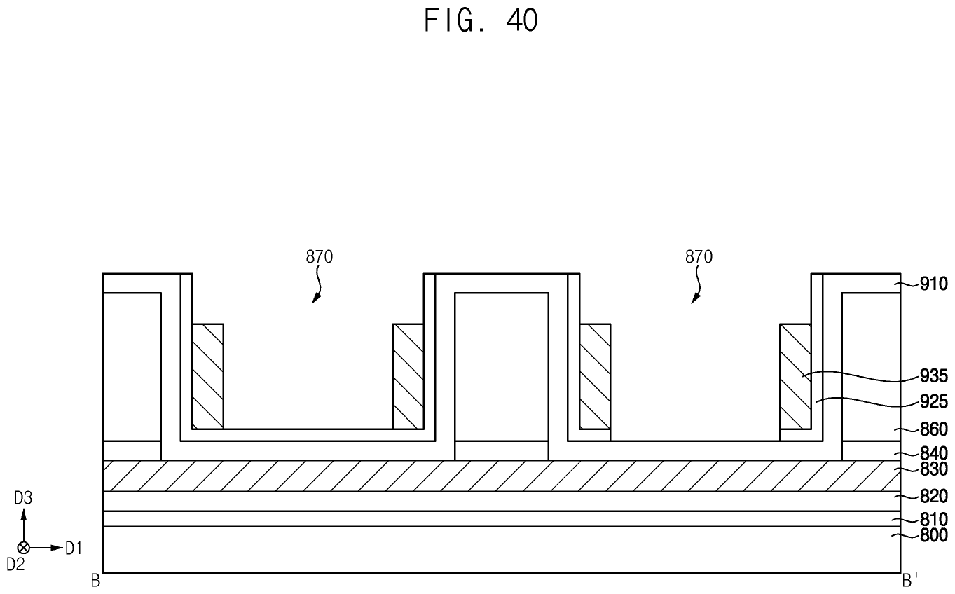

Referring to FIGS. 39 and 40, the second gate electrode layer 930 and the second gate insulation layer 920 may be anisotropically etched to form a second gate electrode 935 and a second gate insulation pattern 925, respectively, on a sidewall of the eleventh opening 870.

In some embodiments, an outer sidewall of the second gate insulation pattern 925 may contact an inner sidewall of the channel layer 910 and an upper surface of an edge portion in the first horizontal direction D1 of the channel layer 910. In some embodiments, a cross-section of the second gate insulation pattern 925 in the first horizontal direction D1 may have an “L” shape.

The second gate electrode 935 may contact an inner sidewall of the second gate insulation pattern 925 and an upper surface of a portion of the second gate insulation pattern 925 that is on the upper surface of the edge portion of the channel layer 910.

An upper portion of the second gate electrode 935 may be removed by, e.g., an etch back process. Thus, an upper surface of the second gate electrode 935 may be lower than an upper surface of the second gate insulation pattern 925, and an upper inner sidewall of the second gate insulation pattern 925 may be exposed. In some embodiments, the upper surface of the second gate electrode 935 may be lower than an upper surface of the third insulating interlayer pattern 860.

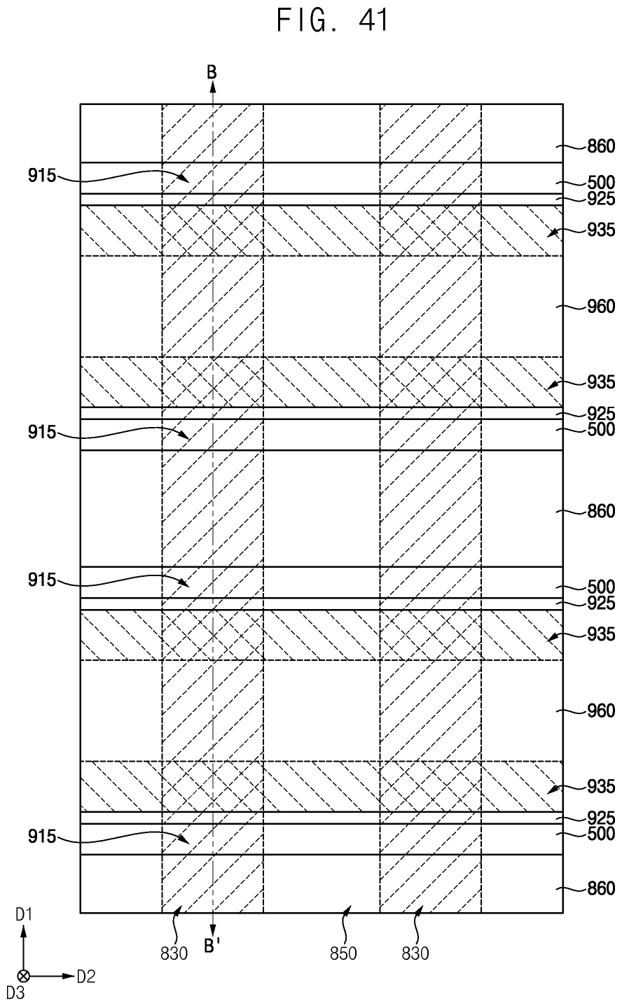

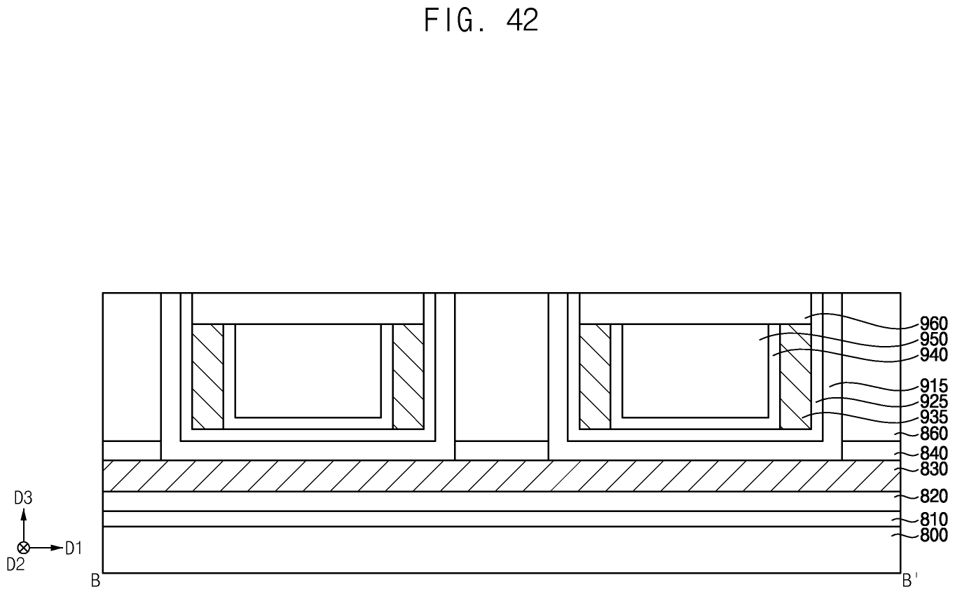

Referring to FIGS. 41 and 42, a twelfth insulation layer may be formed on a sidewall and the upper surface of the second gate electrode 935, the upper inner sidewall and the upper surface of the second gate insulation pattern 925, and an upper surface of the channel layer 910, a fourth insulating interlayer may be formed on the twelfth insulation layer to fill a remaining portion of the eleventh opening 870, and a planarization process may be performed on the fourth insulating interlayer, the twelfth insulation layer, the second gate insulation pattern 925 and the channel layer 910 until the upper surface of the third insulating interlayer pattern 860 is exposed.

The planarization process may include a CMP process and/or an etch back process.

By the planarization process, a fourth insulating interlayer pattern 950 and a twelfth insulation pattern 940 covering a lower surface and a sidewall of the fourth insulating interlayer pattern 950 may be formed in the eleventh opening 870, and the channel layer 910 may be divided into a plurality of channels 915 spaced apart in the first horizontal direction D1. In some embodiments, each of the channels 915 may extend in the second horizontal direction D2, and a cross-section in the first horizontal direction D1 of each of the channels 915 may have a cup shape.

Upper portions of the fourth insulating interlayer pattern 950 and the twelfth insulation pattern 940 may be removed to form a third recess exposing the upper surface of the second gate electrode 935, and a thirteenth insulation pattern 960 may be formed in the third recess.

The thirteenth insulation pattern 960 may be formed by forming a thirteenth insulation layer on the second gate electrode 235, the fourth insulating interlayer pattern 950, the twelfth insulation pattern 940, the second gate insulation pattern 925, the channel 915 and the third insulating interlayer pattern 860 to fill the third recess, and planarizing the thirteenth insulation layer until the upper surface of the third insulating interlayer pattern 860 is exposed.

The channel 915 may be partially removed to form a twelfth opening exposing upper surfaces of the second bit line 830 and the second upper insulating interlayer pattern 850, and a fourteenth insulation pattern 500 may be formed in the twelfth opening. Thus, the channel 915 extending in the second horizontal direction D2 may be divided into a plurality of parts spaced apart in the second horizontal direction D2. As a result, a plurality of channels 915 may be spaced apart in the first and second horizontal directions D1 and D2.

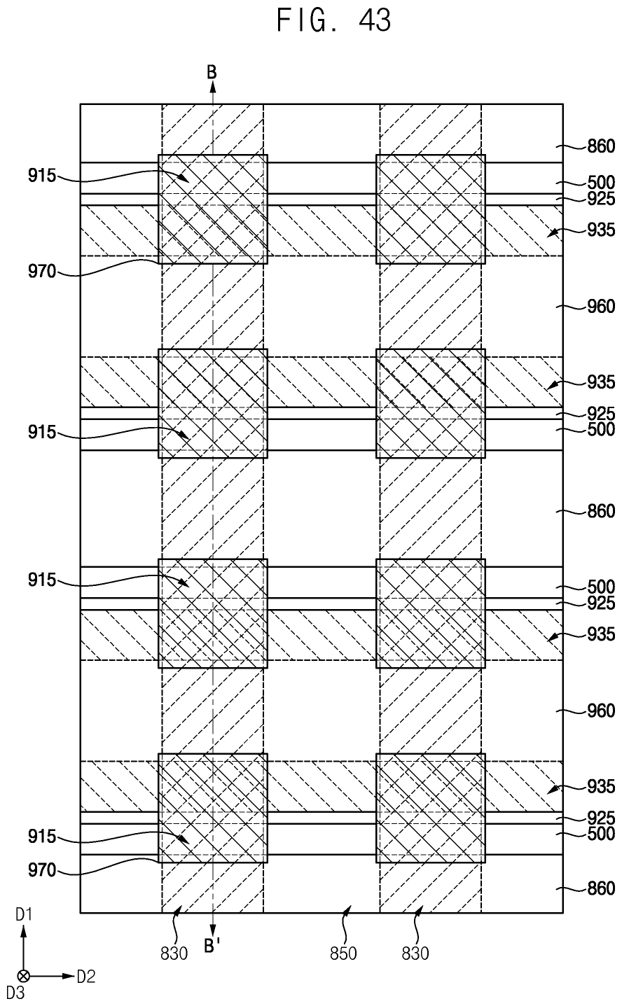

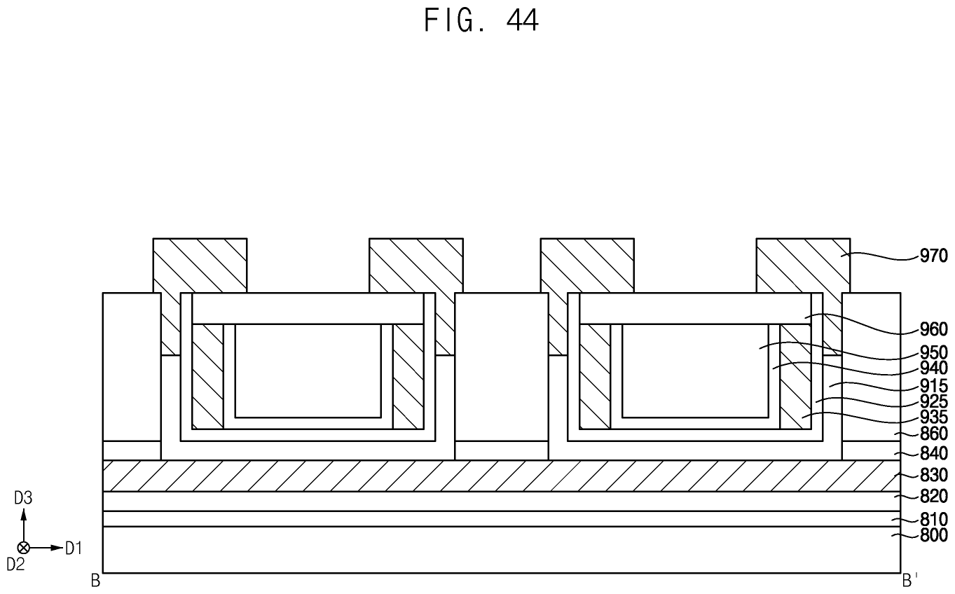

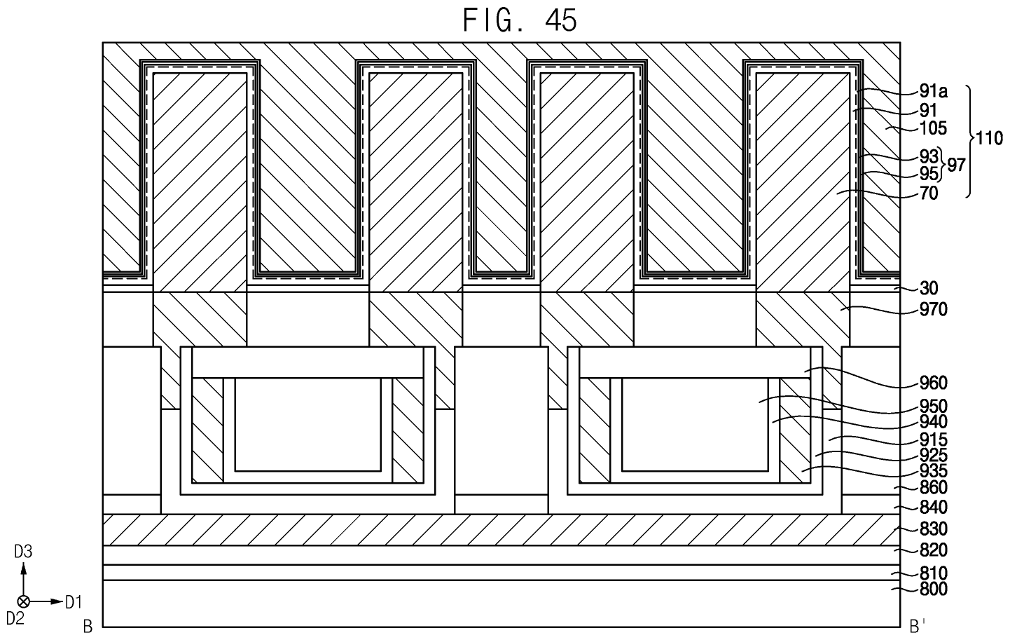

Referring to FIGS. 43 and 44, an upper portion of the channel 915 may be removed to form a fourth recess, and a contact plug layer may be formed on the channel 915, the third insulating interlayer pattern 860, the second gate insulation pattern 925 and the thirteenth insulation pattern 960, and may be patterned to form a contact plug 970 contacting an upper surface of the channel 915.

In some embodiments, a plurality of contact plugs 970 may be spaced apart in the first and second horizontal directions D1 and D2. In some embodiments, the contact plugs 970 may be disposed in a lattice pattern or a honeycomb pattern.

Referring back to FIGS. 32 and 33, a fifth insulating interlayer may be formed on the third insulating interlayer pattern 860, the channel 915, the second gate insulation pattern 925 and the thirteenth insulation pattern 960 to cover the contact plug 970, and an upper portion of the fifth insulating interlayer may be planarized until an upper surface of the contact plug 970 is exposed to form a fifth insulating interlayer pattern 980 covering a sidewall of the contact plug 970.

The capacitor structure may be formed on the contact plug 970 and the fifth insulating interlayer pattern 980 so the fabrication of the semiconductor device may be completed. The lower electrode 70 included in the capacitor 110 may contact an upper surface of the upper contact plug 970.

FIG. 45 is a cross-sectional view illustrating a semiconductor device according to embodiments of the inventive concept. Here, the semiconductor device may be substantially similar to the semiconductor device of FIGS. 32 and 33, except that the capacitor structure does not include the support layer 50. Thus, the dielectric pattern 91 included in the capacitor structure may cover a sidewall and an upper surface of the lower electrode 70 and an upper surface of the first etch stop layer 30, and the upper electrode 105 may be formed on the dielectric pattern 91.

As shown in FIG. 45, the capacitor structure does not include the upper electrode plate 120, however, the inventive concept may not be limited thereto.

While embodiments have been particularly shown and described, it will be understood by one of ordinary skill in the art that variations in form and detail may be made therein without departing from the scope of the following claims.

What is claimed is:

1. A capacitor structure, comprising:
a lower electrode;
a dielectric pattern on the lower electrode, wherein the dielectric pattern includes an oxide of a metal having 4 valence electrons;
an interface structure on the dielectric pattern, wherein the interface structure includes a first interface pattern including a first metal oxide doped with nitrogen, and a second interface pattern including a second metal oxide; and
an upper electrode on the interface structure.

2. The capacitor structure of claim 1, wherein a portion of the dielectric pattern contacting the interface structure further includes nitrogen.

3. The capacitor structure of claim 1, wherein the dielectric pattern includes at least one of hafnium oxide and zirconium oxide.

4. The capacitor structure of claim 1, wherein the first metal oxide doped with nitrogen includes at least one of titanium and niobium.

5. The capacitor structure of claim 1, wherein the second metal includes at least one of titanium, niobium, tantalum, vanadium, and tin.

6. The capacitor structure of claim 1, wherein the first interface pattern has a dielectric constant that ranges from between about 5 to about 30.

7. The capacitor structure of claim 1, wherein a thickness of the first interface pattern is greater than a thickness of the dielectric pattern, and a thickness of the second interface pattern is greater than a thickness of the dielectric pattern.

8. The capacitor structure of claim 7, wherein the thickness of the first interface pattern ranges from between about 5 Å to about 10 Å, the thickness of the second interface pattern ranges from between about 5 Å to about 10 Å, and the thickness of the dielectric pattern ranges from between about 30 Å to about 60 Å.

9. The capacitor structure of claim 1, further comprising:
a support layer on a sidewall of the lower electrode, wherein the dielectric pattern contacts the sidewall of the lower electrode, an upper surface of the support layer and a lower surface of the support layer.

10. The capacitor structure of claim 9, further comprising:
an upper electrode plate on an upper surface of the lower electrode and an upper surface of the support layer, wherein the upper electrode plate includes doped silicon-germanium.

11. A capacitor structure, comprising:
a lower electrode;
a dielectric pattern on the lower electrode and having a first thickness, wherein the dielectric pattern includes an oxide of a first metal;
a first interface pattern on the dielectric pattern and having a second thickness less than the first thickness, the first interface pattern including an oxynitride of a second metal and a third metal, wherein the second metal is different from the third metal;
a second interface pattern on the first interface pattern and having a third thickness less than the first thickness, the second interface pattern including an oxide of the second metal and the third metal; and
an upper electrode on the second interface pattern.

12. The capacitor structure of claim 11, wherein the second metal includes at least one of titanium and niobium, and
the third metal includes at least one of titanium, niobium, tantalum, vanadium, and tin.

13. The capacitor structure of claim 12, wherein the second metal includes titanium, and the third metal includes niobium.

14. The capacitor structure of claim 11, wherein the third metal includes at least one of hafnium and zirconium.

15. The capacitor structure of claim 11, wherein a portion of the first interface pattern contacting the dielectric pattern further includes nitrogen.

16. The capacitor structure of claim 11, wherein the first thickness ranges from between about 30 Å to about 60 Å, and each of the second and third thickness ranges from between about 5 Å to about 10 Å.

17. A semiconductor device, comprising:
a bit line structure on a substrate;
a gate electrode on the bit line, wherein the gate electrode is spaced apart from the bit line;
a gate insulation pattern on a sidewall of the gate electrode;
a channel on a sidewall of the gate insulation pattern, wherein the channel includes an oxide semiconductor material;
a contact plug structure contacting an upper surface of the channel; and
a capacitor structure on the contact plug structure,
wherein the capacitor structure includes:
a lower electrode;
a dielectric pattern on the lower electrode and including an oxide of a metal having 4 valence electrons;
an interface structure including:
a first interface pattern on the dielectric pattern, the first interface pattern including a first metal oxide doped with nitrogen; and
a second interface pattern on the first interface pattern, the first interface pattern including a second metal oxide; and
an upper electrode on the interface structure.

18. The semiconductor device of claim 17, wherein the first metal includes at least one of titanium and niobium.

19. The semiconductor device of claim 17, wherein the second metal includes at least one of titanium, niobium, tantalum, vanadium, and tin.

20. The semiconductor device of claim 17, wherein a thickness of the first interface pattern ranges from between about 5 Å to about 10 Å, a thickness of the second interface pattern ranges from between about 5 Å to about 10 Å, and a thickness of the dielectric pattern ranges from between about 30 Å to about 60 Å.
